(19) United States
(12) Patent Application Publication
(10) Pub. No.: US 2025/0102582 A1
(43) Pub. Date: Mar. 27, 2025

(54) SIMULATING BATTERY DYNAMICS WITH EQUIVALENT CIRCUIT MODELS

(71) Applicant: Joby Aero, Inc., Santa Cruz, CA (US)

(72) Inventors: Alireza Goshtasbi, San Jose, CA (US); Ruxiu Zhao, Campbell, CA (US); Sangwoo Han, Sunnyvale, CA (US); Wenting Ma, San Carlos, CA (US); Jeremy Neubauer, Mountain View, CA (US)

(21) Appl. No.: 18/896,403

(22) Filed: Sep. 25, 2024

Related U.S. Application Data
(60) Provisional application No. 63/585,129, filed on Sep. 25, 2023.
(60) Provisional application No. 63/646,180, filed on May 13, 2024.

(51) Int. Cl. G01R 31/367; B64D 31/16; B64F 5/60; G01R 31/00; G01R 31/382

(52) U.S. Cl. CPC G01R 31/367; B64D 31/16; B64F 5/60; G01R 31/008; G01R 31/382

(57) ABSTRACT

Examples relate to a battery management system with an enhanced equivalent circuit model (ECM) for electric vehicles, including electric vertical takeoff and landing (eVTOL) aircraft. The system includes a memory to store an equivalent circuit model (ECM) configured to dynamically adjust a series resistance component in real-time based on operational data from a lithium-ion battery. This adjustment models lithium depletion effects under high discharge conditions. At least one processor is configured to continuously refine parameters of the ECM by analyzing discrepancies between predicted and actual battery performance, where the adjustments are based on real-time changes in state of charge, temperature, and current.

### BACKGROUND

Batteries are electrochemical devices that convert between chemical and electrical energy. In particular, rechargeable lithium-ion batteries have become a ubiquitous power source for a variety of applications, from consumer electronics to electric vehicles. However, batteries are complex electrochemical systems with nonlinear dynamics that can be difficult to model accurately.

Battery models are important tools that allow simulating and predicting battery behavior under different operating conditions. Accurate battery models are needed for many applications, such as battery management systems, range prediction in electric vehicles, evaluating battery health and state-of-charge, and battery control and optimization.

A variety of battery modeling techniques have been developed, ranging from simple empirical models to detailed electrochemical models. Equivalent circuit models (ECMs) are a popular physics-based modeling approach that represents a battery as an electrical circuit composed of resistors, capacitors, voltage sources, and other elements.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates a schematic diagram of an electric vehicle, such as an eVTOL aircraft, according to some examples.

FIG. 2 is a flowchart illustrating a method, according to some examples, to simulate battery dynamics using an enhanced Equivalent Circuit Model (ECM).

FIG. 3 illustrates an example method of using the enhanced ECM battery model to estimate achievable flight range for an electric aircraft based on a proposed flight plan.

FIG. 4 is a flowchart illustrating a method of managing and predicting the performance of lithium-ion batteries in electric vertical takeoff and landing (eVTOL) aircraft, according to some examples.

FIG. 5 is a flowchart illustrating a method for managing battery performance in an electric vertical takeoff and landing (eVTOL) aircraft, according to some examples.

FIG. 6 is a plan view of a VTOL aircraft according to some examples, which may comprise the electric vehicle shown in FIG. 1.

FIG. 7 is a schematic view of an aircraft energy storage system according to some examples.

FIG. 8 illustrates examples of an electrical architecture for an aircraft.

FIG. 9(A) illustrates a traditional two resistor, two capacitor (2RC) ECM.

FIG. 9(B) illustrates an example of a LD-ECM architecture.

FIG. 9(C) illustrates an example high C-rate pulse data where the terminal voltage is concave as it approaches a lower voltage limit.

FIG. 9(D) illustrates a resulting fit to the same measurements as given in FIG. 9(B) showing significant improvement over the conventional 2RC ECM shown in FIG. 9(A).

FIG. 9(E) illustrates a discrepancy modeling framework used to arrive at the formulation used in FIGS. 9(A) to 9(D).

FIG. 10 is a table illustrating grid points for the discharge lookup table (LUTs).

FIG. 11(A) illustrates the test setup for obtaining the characterization test data for model evaluation.

FIG. 11(B) illustrates the annotated RPT results for the entire test campaign.

FIG. 11(C) illustrates a high C-rate CCP pulse showing minimal impact of current interrupts.

FIG. 11(D) illustrates example high C-rate discharge pulses and their corresponding resistance estimated with the interrupt method.

FIG. 11(E) illustrates an example data set of full discharge data at different temperatures for a single C-rate.

FIG. 11(F) illustrates histograms of data coverage for all constant current (CCP and FD) tests.

FIG. 11(G) illustrates a MPP example and data coverage histograms.

FIG. 12 is a table illustrating the DOE for constant current pulse characterization (CCP).

FIG. 13(A) illustrates creating the cost function for parameter identification using the variable weight for RC-only error.

FIG. 13(B) illustrates example LUT results obtained with zero regularization, where the black boundary indicates the convex hull of the test data coverage in this example fitting case.

FIG. 14(A) illustrates the performance of examples of the enhanced ECM model on training data and the RMSE on 6C CCP data with different parameter representations.

FIG. 14(B) illustrates the performance of examples of the enhanced ECM model on training data and 6C pulses at two temperatures with the corresponding ohmic resistance.

FIG. 14(C) illustrates exemplary parameter LUTs at 6C discharge current.

FIG. 15(A) illustrates the impact of a fine-tuning step and shows the voltage prediction error histograms before and after the fine tuning.

FIG. 15(B) illustrates the impact of fine-tuning step and shows example MPP profiles and the fit quality before and after the fine tuning step.

FIG. 16(A) illustrates a validation flight data set including example power profiles and corresponding cell voltage response for one-hop missions with the five different variants.

FIG. 16(B) illustrates a validation flight data set including example power profiles and corresponding cell voltage response for two-hop missions with three different variants.

FIG. 16(C) illustrates a validation flight data set including the distributions of key metrics through entire flights as well as at the beginning of reserve section for one- and two-hop flights.

FIG. 17 illustrates the performance of some examples of the enhanced ECM model on several one- and two-hop flights in the validation data set.

FIG. 18(A) illustrates the error statistics on all replicates of validation flights including voltage and reserve time prediction error distributions for one- and two-hop flights.

FIG. 18(B) illustrates error statistics on all replicates of validation flights including predicted vs. true reserve values.

FIG. 18(C) illustrates a comparison of voltage and reserve time prediction error distributions for all flights obtained by running the model in current and power modes.

FIG. 19 is a diagrammatic representation of a computer system within which a set of instructions may be executed for causing the machine to perform any one or more of the methodologies discussed herein, according to some examples.

### DETAILED DESCRIPTION

### Introduction

Lithium-ion batteries are used in powering electric vehicles, such as electric vertical takeoff and landing (eVTOL) aircraft, demanding high power and energy density while maintaining fault tolerance. These batteries face challenges, particularly when operating under conditions that require high discharge rates, such as during emergency maneuvers or system faults that may lead to one or more battery packs going offline. Under such circumstances, the batteries may need to support discharge currents significantly higher than their normal operational rates, which can stress the battery's capacity and impact its voltage stability and overall health.

Battery management systems (BMS) are used for monitoring and managing these high-demand scenarios to prevent potential failures such as rapid altitude loss. These systems may use models that predict and estimate battery states to ensure safe and efficient operation. The models range from high fidelity physics-based models, which provide detailed insights into battery internals but are often complex and computationally intensive, to more simplified empirical models like equivalent circuit models (ECMs). ECMs are favored in some real-time applications due to their simpler structures and lower computational demands, making them suitable for onboard systems where resources are limited.

However, traditional ECMs, while effective at lower discharge rates, may fail to accurately predict battery behavior under the high discharge rates encountered in eVTOL applications. This limitation has led to the development of advanced ECMs that incorporate mechanisms to account for phenomena such as solid phase diffusion and lithium depletion, which significantly affect battery performance under high discharge conditions. These advanced models aim to provide more accurate predictions by considering the rapid changes in state of charge and temperature, which are critical under eVTOL operational conditions.

Despite advancements, accurately parameterizing these models remains a challenge due to the dynamic nature of eVTOL flights. The parameters of the battery model must adapt to varying conditions of state of charge, temperature, and current to maintain accuracy, which is not always feasible with static parameter sets derived from standard conditions. This necessitates ongoing research and development to refine these models, ensuring they can reliably support the safety requirements and operational demands of eVTOL aircraft.

### Overview

Electric vertical takeoff and landing (eVTOL) aircraft represent a transformative advancement in aviation technology, primarily designed to operate in urban environments. These aircraft require robust and reliable power sources, typically provided by lithium-ion batteries, known for their high energy density and efficiency. However, managing these batteries effectively, especially under the high-demand conditions typical of eVTOL operations, presents significant challenges.

The described examples primarily focus on battery management systems (BMS) and methods that enhance the performance and safety of lithium-ion batteries during flight operations, particularly in electric vertical takeoff and landing (eVTOL) aircraft. These systems utilize advanced modeling techniques, such as the enhanced equivalent circuit model (ECM), to dynamically manage and predict battery behavior under various operational stresses, including high discharge rates.

While example applications of these technologies is in the aviation sector, particularly for eVTOL aircraft, the versatility of the described models allows for broader applications. For example, these battery management systems can be effectively utilized by charge controllers in ground support equipment designed for charging electric aircraft. This equipment plays a role in maintaining the readiness and efficiency of electric aircraft by ensuring that batteries are charged safely and efficiently.

In the context of ground support equipment, the ECM can enhance the functionality of charge controllers. These controllers are responsible for managing the power flow to the aircraft batteries, ensuring that charging is performed within safe parameters to maximize battery life and performance. The adaptability of the ECM allows it to be tailored to the specific charging profiles required by different types of electric aircraft batteries, providing a customized approach that can adapt to various battery chemistries and configurations.

By continuously monitoring battery conditions such as state of charge, temperature, and current during the charging process, the ECM can make dynamic adjustments to the charging parameters. This not only optimizes the charging process but also helps prevent conditions that could lead to battery damage, such as overheating or overcharging.

Furthermore, the environmental adaptation module within the ECM, which adjusts model parameters in response to detected environmental conditions such as temperature, humidity, and atmospheric pressure, adds an additional layer of optimization for ground support equipment. This feature ensures that the charging process remains efficient and safe even under varying environmental conditions, which is often the case in outdoor airport settings.

The ability of the ECM to provide predictive performance metrics through its display interface also enhances the operational efficiency of ground support equipment. Operators can receive real-time updates and forecasts on battery status, which aids in planning and managing the charging schedules for multiple aircraft, thereby improving turnaround times and overall airport efficiency.

Examples describe an enhanced equivalent circuit model (ECM), which may be a component of the BMS as noted above. An example model is designed to dynamically adjust its parameters in real-time based on the operational data it receives from the battery. This data includes the battery's state of charge, temperature, and current, which are critical factors affecting battery performance and health. The ECM uses this data to predict and manage the battery's behavior, particularly under high discharge rates that are common during takeoffs, landings, or emergency maneuvers.

One of the components of the ECM is the series resistance component, which is used for modeling the lithium depletion effects under high discharge conditions. Lithium depletion can impact the battery's ability to deliver the required power and, if not managed properly, can lead to rapid voltage drops that may compromise the aircraft's performance and safety. The series resistance component in the ECM is adjusted in real-time, ensuring that the model remains accurate under varying operational conditions.

To refine the accuracy of the ECM, a data-driven discrepancy model may be employed. This model identifies the minimal modifications needed to align the ECM's predictions with the actual performance observed during battery operation. This approach allows for continuous refinement of the ECM parameters, enhancing the model's reliability and accuracy. Sparse regression techniques may be used within this framework to pinpoint the simplest system corrections based on observed prediction errors, thereby maintaining the model's efficiency and effectiveness.

The ECM also includes multiple resistor-capacitor (RC) pairs. These pairs may be used for capturing the dynamic voltage response of the battery. The integration of the series resistance component with these RC pairs allows the ECM to simulate the battery's behavior more accurately under various load conditions. The parameters of these RC pairs, along with the series resistance component, are adaptively modified based on real-time data inputs, which helps in fine-tuning the model's predictions.

Operational data for the ECM's function may be derived from sensors directly attached to the battery. These sensors measure temperature, state of charge, and current, providing real-time data that is helpful for the accurate functioning of the ECM. Additionally, a display interface may be included in the system, offering real-time and predictive metrics on battery performance. This feature aids pilots and maintenance crews in monitoring the battery's status and making informed decisions regarding aircraft operation.

The described ECM is not only applicable to eVTOL aircraft but can also be adapted for use in various types of electric vehicles, such as drones, electric cars, and marine vehicles. By customizing the model parameters to reflect the typical operating conditions and discharge rates specific to each vehicle type, the ECM can provide tailored battery management solutions across different applications.

Furthermore, the ECM includes an environmental adaptation module. This module dynamically adjusts the model parameters in response to detected environmental conditions such as temperature, humidity, and atmospheric pressure. Such adaptations are crucial for maintaining battery performance and safety during flight, especially in varying climatic conditions.

The described examples of battery management systems and methods provide a comprehensive solution to managing the performance and safety of lithium-ion batteries in high-demand applications like eVTOL aircraft. By employing advanced modeling techniques and real-time data analysis, these systems ensure that the batteries can meet the rigorous demands of flight operations while maintaining their efficiency and longevity. This technology not only enhances the operational capabilities of eVTOL aircraft but also contributes to the broader adoption and reliability of electric vehicles in various sectors.

### Operational Details

Implementing examples of the enhanced equivalent circuit model (ECM) for lithium-ion batteries into applications like electric vertical takeoff and landing (eVTOL) aircraft involves several operations. These operations seek to deliver that the model is not only theoretically sound but also practical and reliable for real-world applications. Here is a detailed breakdown of these processes.

First operation is a model development and enhancement process. This process includes a base model setup. Starting with an ECM comprising resistor-capacitor (RC) pairs that simulate the battery's dynamic behavior. Then an enhancement is added for high discharge rates. This involves integrating additional components into the model, such as a dynamic series resistance, to account for phenomena like lithium depletion which are critical at high discharge rates observed in eVTOL operations.

The next operation is a parameterization process. This involves data collection such that testing in conducted under varied conditions to gather data. This includes constant current pulses (CCP) at different rates (e.g., the 6C CCP), temperatures, and states of charge. Moreover, lookup table (LUTs) are developed for model parameters across different operational conditions using the collected data. These tables store pre-computed values for parameters like resistance and time constants, which vary with SOC, temperature, and current.

A third operation is a model calibration process. This process involves fitting the model to the data and use the collected data to fit the model parameters. This may involve optimization techniques to minimize the error between the model predictions and actual observed data. Another part of this process may involve applying regularization techniques to avoid overfitting and ensure smooth parameter transitions across different operating conditions.

A fourth operation is a validation process. The model is validated using a separate set of test data that was not used during the model fitting. This operation is to test the model's accuracy and reliability. In addition, performance metrics are used. These performance metrics focus on relevant performance metrics such as the prediction accuracy of reserve time, which is used for flight safety and operational planning in eVTOL applications.

A fifth operation is integration into a battery management system (BMS). This involves real-time implementation that integrates the model into the BMS of the eVTOL aircraft. This involves programming the BMS to use the ECM and its LUTs for real-time state estimation and performance prediction. This operation also includes implementing a feedback mechanism to update or recalibrate the model based on ongoing operational data and feedback to adapt to changes in battery behavior over time due to aging or other factors.

A sixth operation is operational deployment, which involves monitoring and diagnostics. This involves using the model within the BMS to continuously monitor the battery's state and predict future performance, providing crucial data for flight control systems and pilot alerts. Moreover, the model's output is leveraged to perform safety checks, ensuring that the battery can meet the power demands of all flight phases, especially emergency scenarios requiring high discharge rates.

A seventh operation includes continuous improvement. This includes data collection post-deployment. Data continues to be collected during actual operations to further refine and enhance the model. Additionally, model updates are used to periodically update the model parameters and LUTs based on new data and insights gained from operational experience. These operations enable examples of the enhanced ECM to be used in operational settings, providing support for battery management in applications like eVTOL aircraft, where reliability and accuracy are paramount.

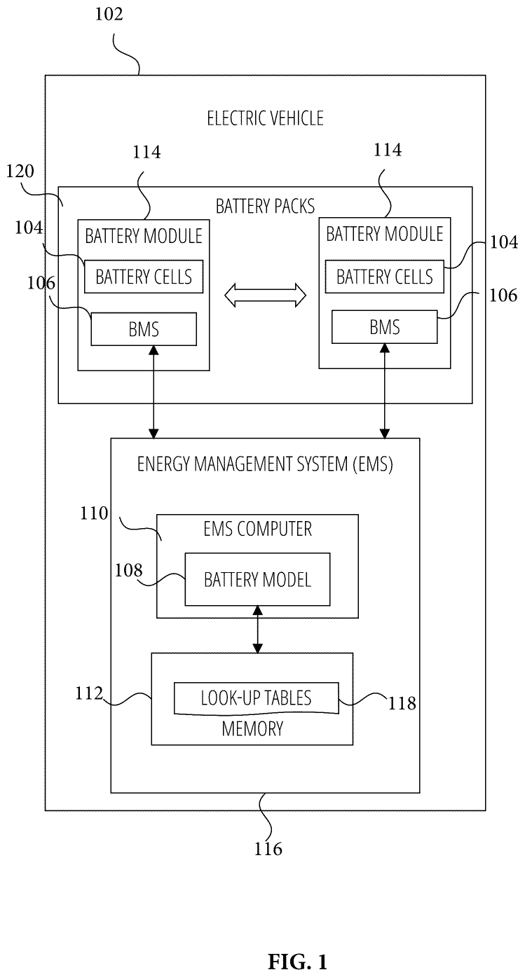

FIG. 1 illustrates a schematic diagram of an electric vehicle 102, such as an eVTOL aircraft, according to some examples. The electric vehicle 102 includes multiple isolated battery packs 120, which in turn may include several battery modules 114. Each battery module 114 contains several battery cells 104 and has an embedded battery management system (BMS) 106. Each battery module 114 is communicatively connected (e.g., via a CAN bus) to an energy management system (EMS) 116 of the electric vehicle 102. The EMS 116 comprises an EMS computer 110 that retrieves and uses a battery model 108 from memory 112 to perform various energy management functions.

Functions performed by the EMS 116 include real-time battery state estimation algorithms that track key parameters like state of charge, state of health, and core temperatures. The EMS 116 leverages these estimates to enact safety features that protect the battery modules 114 from damage, such as limiting charge/discharge rates and balancing state of charge between battery modules.

The EMS 116 also runs battery charge optimization algorithms that adapt charging based on cell conditions to maximize lifetime. During flight, the EMS 116 coordinates load scheduling across packs, ensuring power demands are met safely and efficiently. The EMS 116 provides analytics and dashboards to inform maintenance practices. It logs extensive data for model parameterization and validation. The EMS 116 also manages bi-directional communication with the battery management systems to synchronize cell-level data.

One function of the EMS 116 is to provide accurate range estimations to the pilot and other aircraft systems. When a pilot enters a proposed flight plan into a mission computer of the electric vehicle 102, the EMS 116 may perform the following operations to estimate the achievable range. First, the EMS 116 may perform a load profile generation. The EMS 116 uses the proposed route to generate a nominal load profile that estimates the power draw over the course of the flight plan. It considers different phases like takeoff, climb, cruise, descent, landing, and reserves power for contingencies. Second, the EMS 116 may perform a fault profile generation. The EMS 116 generates additional load profiles representing worst-case fault scenarios such as loss of a propulsor or battery failure. Third, the EMS 116 may perform a battery model simulation, in which that EMS 116 runs simulations of a battery model 108 under each load profile to predict pack voltages and usage. The battery model 108 seeks to accurately capture nonlinear dynamics like the knee-drop phenomenon at high discharge rates.

Fourth, the EMS 116 may perform a limit analysis whereby it checks whether battery voltage or state of charge limits are violated for any of the profiles. If so, it may iteratively modify the flight plan by reducing cruise distance until limits are satisfied. Fifth, the EMS 116 may perform range reporting. Once a feasible flight plan is found, the EMS 116 reports the achievable range back to the pilot. It also provides projected end-of-flight reserves like remaining hover time. Finally, the EMS 116 may perform a model adaptation. During flight, the EMS 116 continuously updates model parameters to account for cell aging and other changes. After landing, it may perform automated or semi-automated battery tests to calibrate the model. By considering realistic load profiles and battery dynamics, the EMS 116 provides pilots with accurate range estimations for safe flight planning.

In some examples, the battery model 108 comprises an enhanced Equivalent Circuit Model (ECM) to simulate battery dynamics. The enhanced ECM represents a battery cell 104 as an electrical circuit comprising passive circuit elements such as resistors and capacitors. Circuit element values may be parameterized by look-up tables 118 to capture nonlinear effects of battery state of charge, temperature, age, and discharge current on model dynamics. More specifically, circuit element values in the enhanced ECM may be parameterized by the look-up tables 118 to capture the nonlinear effects of battery state of charge, temperature, age, and discharge current on model dynamics. By using multidimensional look-up tables 118 for each circuit element, the enhanced ECM can adapt its dynamics based on the current battery state and operating scenario. This allows for the capturing of complex nonlinear battery behaviors across a wide range of conditions.

The enhanced ECM may further include a dynamically variable resistor configured to model the knee-drop phenomenon observed during high-power discharge events. By tuning the ECM parameters based on laboratory characterization data and measurements obtained during in-situ operation, the enhanced ECM may be configured to closely match actual battery performance across a wide range of operating conditions. This high-fidelity simulation capability enables the EMS 116 to reliably analyze complex load profiles and fault scenarios when computing an achievable flight range for a given flight plan.

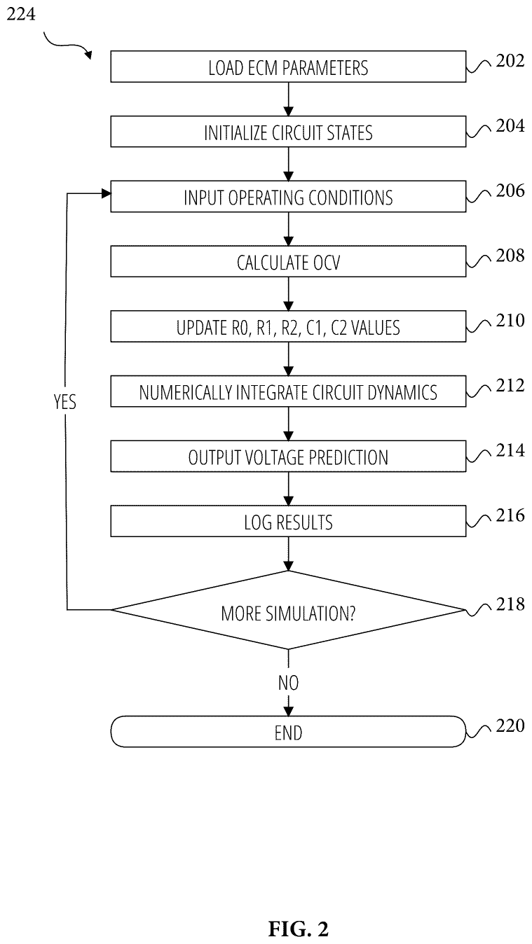

FIG. 2 is a flowchart illustrating a method 224, according to some examples, to simulate battery dynamics using the enhanced Equivalent Circuit Model (ECM). At block 202, the ECM circuit parameters are loaded from the memory 112 into the EMS computer 110. At block 204, the initial states of the RC pairs in the enhanced ECM are set to appropriate values by the EMS computer 110. Specifically, initial voltages V1 and V2 across the RC pairs are specified along with an initial resistance value for a variable resistor. Initial values may be obtained from previous simulations.

At block 206, the specific operating conditions for the desired battery simulation scenario are input to the EMS computer 110 by the user. First, the cell temperature is specified, in degrees Celsius (° C.), which should be assumed for the simulation. For example, the user may set the temperature to 35° C. or higher to simulate a hot operating environment. Second, the initial state of charge (SOC), in percentage, is specified for the beginning of the simulation. For instance, the user may set the initial SOC to 80% to simulate a partially discharged cell condition. Third, the full discharge current profile, in amperes (A), that should be applied to the cell during the simulation is input. This defines the current waveform that will be used to simulate discharging the cell over time. The profile may contain constant current segments at different levels, pulse currents, sine waveforms, etc. For example, to evaluate high discharge performance, the user may input a current profile that applies 10C pulse (10 times the cell capacity) discharge currents to simulate demanding loads. The profile length sets the total simulation duration.

At block 208, using the SOC value input in block 206, the EMS computer 110 uses an open circuit voltage (OCV) look-up table 118 loaded in block 202 to determine the OCV value corresponding to the specified SOC. This OCV may be used in calculating the cell's terminal voltage. At block 210, the EMS computer 110 uses the look-up tables 118 loaded in block 202 for R0, R1, R2, C1, and C2 to update the values of the resistive and capacitive elements in the ECM circuit model based on the operating conditions set in block 206. This captures the dependence of these passive circuit components on factors like temperature and discharge current.

At block 212, the EMS computer 110 numerically integrates the dynamics of the enhanced ECM over time to simulate a response of a battery cell 104 to the discharge current input. An ordinary differential equation (ODE) solver integrates the voltage dynamics of the RC pairs (V1, V2) and the differential equation governing growth of R_ld. At each timestep, the solver updates V1, V2, and R_ld. At block 214, once the simulation is complete, the EMS computer 110 calculates the cell's terminal voltage by combining the voltages across the ECM circuit elements as determined during the numerical integration. This terminal voltage prediction reflects the cell's simulated response to the specified operating conditions.

At block 216, the EMS computer 110 logs the simulation results, including the terminal voltage waveform. This data can be used to validate the accuracy of the enhanced ECM and tune the parameters to improve fidelity. At decision block 218, the EMS computer 110 checks if additional operating conditions need to be evaluated. If so, the method 224 returns to block 206 to simulate the cell response under a new set of conditions. At done block 220, the simulation is complete, and the process ends.

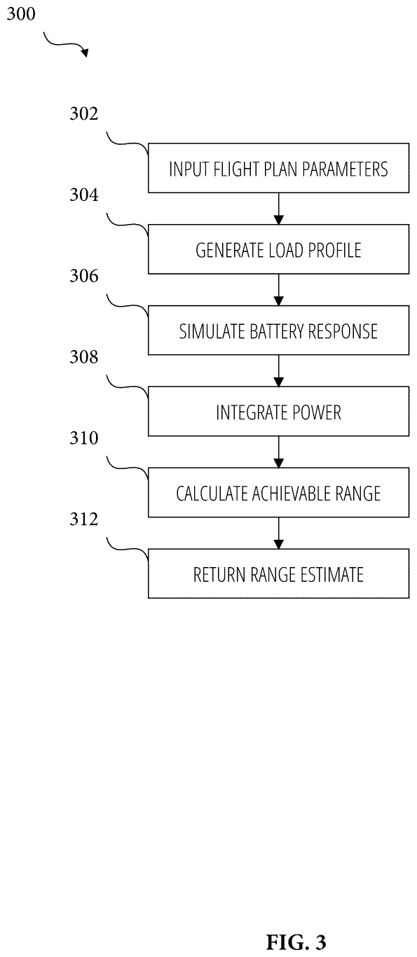

FIG. 3 illustrates an example method 300 of using the enhanced ECM battery model to estimate achievable flight range for an electric aircraft based on a proposed flight plan. Although the example method 300 depicts a particular sequence of operations, the sequence may be altered without departing from the scope of the present disclosure. For example, some of the operations depicted may be performed in parallel or in a different sequence that does not materially affect the function of the method 300. In other examples, different components of an example device or system that implements the method 300 may perform functions at substantially the same time or in a specific sequence.

At block 302, the EMS computer 110 receives key flight plan parameters from the pilot via the aircraft's mission planning interface or the ground support equipment. These parameters include total flight distance, takeoff weight based on passenger load, requested cruise altitude and airspeed, forecast winds aloft, reserve fuel calculations, etc. These define the mission profile. At block 304, the EMS computer 110 uses aircraft performance models and data tables to estimate the expected electrical load profile over the entire flight plan. Power levels are calculated for different phases like takeoff, climb, cruise, descent, and reserves. Effects like changing air density with altitude are considered. Load transients during configuration changes are modeled. The result is a time-series of expected electrical power draw for the proposed mission.

At block 306, the EMS computer 110 initializes the ECM to the current state of charge, temperature, age, and health status. It then numerically integrates the electrical dynamics equations of the ECM using an ODE solver. The previously generated load profile is input as the discharge current over time. This simulates the battery's nonlinear voltage response over the full flight, capturing effects like knee-drop at high power. At block 308, at each timestep of the ECM simulation, the EMS computer 110 calculates instantaneous power output as (current*voltage). It numerically integrates power over time to determine the total electrical energy that could be supplied by the battery for the given mission profile. Loss factors are considered.

At block 310, using the total usable energy from the simulation, the EMS computer 110 calculates an achievable cruise range by dividing by the average power expected during cruise based on altitude, speed, and wind. Reserve energy margins as required by regulators are subtracted. The result is a prediction of a maximum possible range. At block 312, the EMS computer 110 provides the estimated achievable flight range to the pilot's mission planning interface. Additional metrics like remaining hover time may also be displayed. This enables flight planning to manage battery energy. Thus, the method 300 leverages the high-fidelity ECM battery model to estimate achievable range for a proposed electric aircraft flight, considering nonlinear dynamics. The EMS computer 110 performs the simulation using the load profile and battery state data.

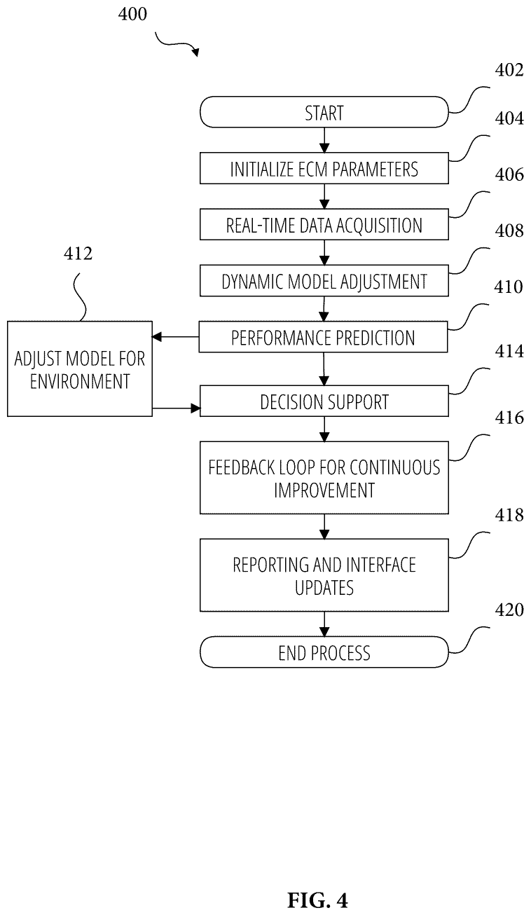

FIG. 4 is a flowchart illustrating a method 400 of managing and predicting the performance of lithium-ion batteries in electric vertical takeoff and landing (eVTOL) aircraft, according to some examples. This flowchart provides a visual representation of the operational use of an enhanced Equivalent Circuit Model (ECM) within a battery management system (BMS) or other battery charging application. Although the example method depicted in FIG. 4 shows a particular sequence of operations, the sequence may be altered without departing from the scope of the present disclosure. For example, some of the operations depicted may be performed in parallel or in a different sequence that does not materially affect the function of the method. In some examples, different components of an example device or system that implements the method may perform functions at substantially the same time or in a specific sequence.

The method 400 starts at a start block 402. At block 404, the BMS 106 initializes the ECM parameters based on baseline data from battery specifications and initial testing. This initialization is performed by the processing unit of the BMS, which configures the ECM to accurately represent the battery's behavior based on its specific characteristics and operational requirements. At block 406, real-time data acquisition is conducted. For example, sensors integrated into the eVTOL aircraft's battery system collect data on current, voltage, temperature, and state of charge. This data is then transmitted to the BMS 106 where it is preprocessed to ensure accuracy and reliability before being used in subsequent operations.

At block 408, dynamic model adjustment occurs within the BMS 106. At a high level, the BMS 106 processes incoming data to evaluate the battery's operational state. This evaluation involves general assessments of battery metrics such as charge levels and overall health. Based on these assessments, the BMS adjusts the battery's management parameters to align with the current operating conditions and data inputs. More specifically, the BMS 106 utilizes the enhanced ECM to process data from sensors that monitor various aspects of the battery's performance, including temperature, current flow, and voltage. This data is used for determining the state of charge and the health status of the battery. The ECM, by analyzing this data, helps in recalibrating resistance values within the battery's circuit model or updating the estimation of the state of charge to better reflect the real-time condition of the battery.

In some specific examples, the recalibration of resistance values may include adjustments to the series resistance components and the parameters of the resistor-capacitor (RC) pairs within the ECM. These adjustments are based on discrepancies identified between predicted and actual battery performance, which might be influenced by factors such as temperature fluctuations, changes in battery load, or aging effects on battery components. For instance, if the actual battery temperature is higher than what the model predicts, the series resistance might be increased to account for faster degradation rates at higher temperatures. Similarly, updates to the state of charge estimation might involve refining the algorithm that integrates current input and voltage output data to produce more accurate charge level readings, especially under dynamic load conditions. These adjustments ensure that the ECM provides a reliable and accurate representation of the battery's current state, facilitating battery management and operational efficiency.

At block 410, performance prediction is executed. The BMS 106 uses the updated ECM to predict short-term battery performance, such as potential voltage drops and energy output. Additionally, it assesses the long-term health and expected lifespan of the battery based on extended ECM predictions and historical data analysis. This predictive functionality supports operational decisions and fault detection within the eVTOL aircraft. In some examples, the method 400 may, at block 412 include additional operations such as dynamically adjusting model parameters in response to detected environmental conditions such as temperature, humidity, and atmospheric pressure during flight, using an environmental adaptation module within the ECM. This adaptation ensures that the ECM remains accurate under varying operational conditions.

At block 414, decision support is provided based on the ECM outputs. The BMS 106 offers real-time decision support for battery usage and charge management. It also utilizes ECM outputs to detect anomalies or faults in battery performance and initiates appropriate responses or maintenance procedures. At block 416, a feedback loop for continuous improvement is implemented. The BMS 106 collects performance feedback on the accuracy and reliability of the ECM predictions from actual battery operations. Based on this feedback, the ECM is refined and recalibrated to enhance prediction accuracy and operational efficiency.

At block 418, reporting and interface updates are conducted. The BMS 106 updates display interfaces to provide pilots and technicians with real-time insights into battery status and alerts. It also generates detailed reports on battery performance and ECM effectiveness for review by engineering and maintenance teams. The method 400 then finishes at end block 420.

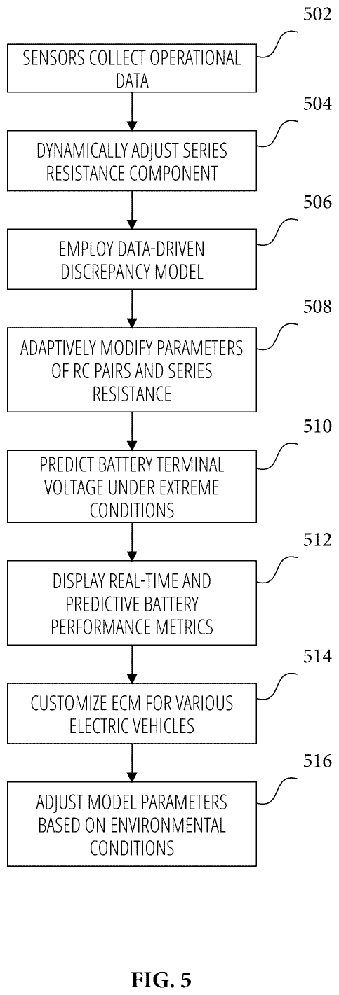

FIG. 5 is a flowchart illustrating a method for managing battery performance in an electric vertical takeoff and landing (eVTOL) aircraft, according to some examples. Examples of the method dynamically adjust and refine an equivalent circuit model (ECM) based on real-time operational data from a lithium-ion battery. FIG. 5, through its detailed depiction of the method steps, illustrates a comprehensive approach to managing battery performance in eVTOL aircraft, ensuring safety, reliability, and efficiency in battery usage.

Although the example method depicted in FIG. 5 shows a particular sequence of operations, the sequence may be altered without departing from the scope of the present disclosure. For example, some of the operations depicted may be performed in parallel or in a different sequence that does not materially affect the function of the method. In some examples, different components of an example device or system that implements the method may perform functions at substantially the same time or in a specific sequence.

At block 502, sensors configured within an eVTOL aircraft 600 collect operational data directly from the lithium-ion battery. This data includes temperature, state of charge, and current measurements. These sensors provide real-time data helpful for the subsequent steps in the battery management process. At block 504, an enhanced ECM dynamically adjusts a series resistance component in real-time. This adjustment is based on the operational data received from the sensors. The series resistance component is used for modeling lithium depletion effects under high discharge rates, which are common in eVTOL operations, such as during takeoff and landing phases or fault scenarios. The series resistance component is integrated or deployed in series with multiple resistor-capacitor (RC) pairs within the ECM. This integration helps in refining the overall resistance modeling of the battery, enhancing the accuracy of the ECM under varying operational conditions.

At block 506, in more specific examples, the adjustment of the series resistance component may use a data-driven discrepancy model. This model uses sparse regression techniques to identify the minimal modifications required to align ECM predictions with the observed battery performance. Sparse regression helps in determining dynamical system corrections based on prediction errors, optimizing the computational efficiency of the adjustments. At block 508, the parameters of the RC pairs and the series resistance component are adaptively modified. This modification is based on a combination of inputs including the real-time data of state of charge, temperature, and current from the sensors. This adaptive modification allows the ECM to respond dynamically to changes in the battery's operational environment, maintaining optimal performance.

At block 510, the enhanced ECM, now refined with updated parameters, predicts the battery terminal voltage under extreme discharge conditions. These conditions include not only regular operations but also fault scenarios where the battery might be subjected to unusually high discharge rates. At block 512, the refined parameters of the enhanced ECM are used to display real-time and predictive battery performance metrics on a display interface within the eVTOL aircraft. This display provides pilots and maintenance crews with critical information about the battery's status and expected performance, aiding in decision-making processes during flights.

At block 514, the enhanced ECM is further adapted for use in various types of electric vehicles by customizing the model parameters to reflect typical operating conditions and discharge rates specific to each vehicle type. This customization ensures that the enhanced ECM can be effectively used across different platforms, maximizing its utility. At block 516, the enhanced ECM dynamically adjusts model parameters in response to detected environmental conditions such as temperature, humidity, and atmospheric pressure during flight. This adjustment is facilitated by an environmental adaptation module within the enhanced ECM, ensuring that the model remains accurate under diverse environmental conditions.

### Example Vehicle Overview

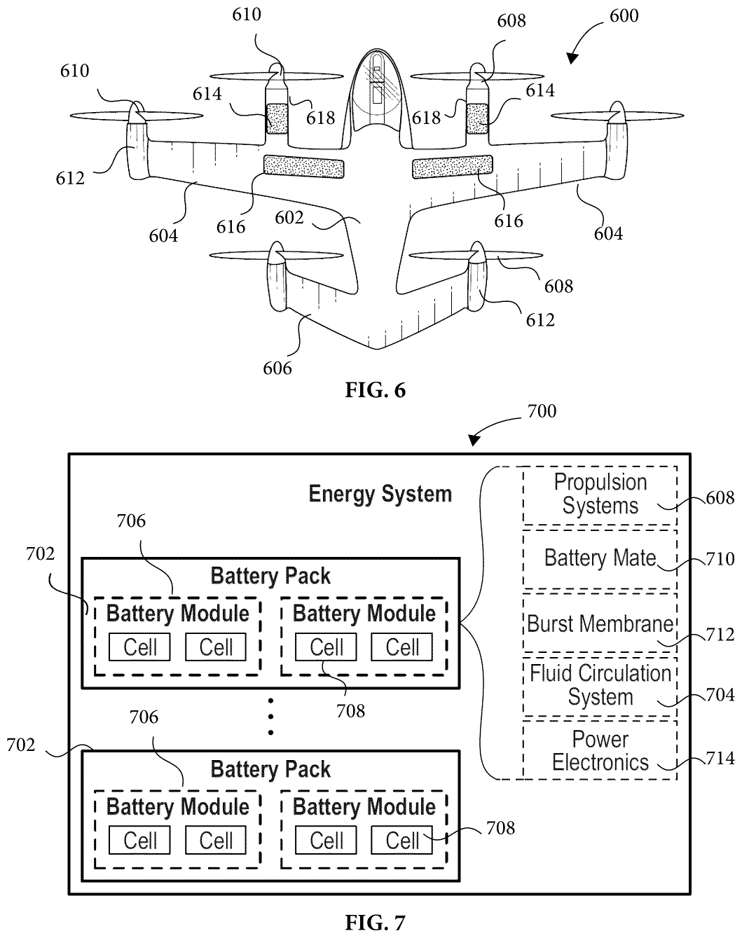

FIG. 6 is a plan view of a VTOL aircraft 600 according to some examples, which may comprise the electric vehicle 102. The aircraft 600 includes a fuselage 602, two wings 604, an empennage 606, and propulsion systems 608 embodied as tiltable rotor assemblies 610 located in nacelles 612. The aircraft 1400 includes one or more nonlinear and isolated power sources in the example form of battery packs 702 embodied in FIG. 6 as nacelle battery packs 614 and wing battery packs 616. In the illustrated example, the nacelle battery packs 614 are located in inboard nacelles 618, but it will be appreciated that the nacelle battery packs 614 could be located in other nacelles 612 forming part of the aircraft 600. The aircraft 600 will typically include associated equipment such as an electronic infrastructure, control surfaces, a cooling system, landing gear, and so forth.

The wings 604 function to generate lift to support the aircraft 600 during forward flight. The wings 604 can additionally or alternately function to structurally support the battery packs 702, battery module 706 and/or propulsion systems 708 under the influence of various structural stresses (e.g., aerodynamic forces, gravitational forces, propulsive forces, external point loads, distributed loads, and/or body forces, and so forth).

### Energy Storage System

FIG. 7 is a schematic view of an aircraft energy storage system 700 according to some examples, which may be managed by the EMS 116. As shown, the energy storage system 700 includes one or more battery packs 702. Each battery pack 702 may include one or more battery modules 706, which in turn may comprise a number of cells 708.

Typically associated with a battery pack 702 are one or more propulsion systems 608, a battery mate 710 for connecting it to the energy storage system 700, a burst membrane 712 as part of a venting system, a fluid circulation system 704 for cooling, and power electronics 714 for regulating delivery of electrical power (from the battery during operation and to the battery during charging) and to provide integration of the battery pack 702 with the electronic infrastructure of the energy storage system 700. As discussed in more detail below, the propulsion systems 608 may comprise multiple rotor assemblies.

The electronic infrastructure and the power electronics 714 can additionally or alternately function to integrate the battery packs 702 into the energy storage system 700 of the aircraft. The electronic infrastructure can include the BMS 106, power electronics (HV architecture, power components, and so forth), LV architecture (e.g., vehicle wire harness, data connections, and so forth), and/or any other suitable components. The electronic infrastructure can include inter-module electrical connections, which can transmit power and/or data between battery packs and/or modules. Inter-modules can include bulkhead connections, bus bars, wire harnessing, and/or any other suitable components.

The battery packs 702 function to store electrochemical energy in a rechargeable manner for supply to the propulsion systems 608. Battery packs 702 can be arranged and/or distributed around the aircraft 600 in any suitable manner. Battery packs can be arranged within wings (e.g., inside of an airfoil cavity), inside nacelles, and/or in any other suitable location on the aircraft. In a specific example, the energy storage system 700 includes a first battery pack within an inboard portion of a left wing and a second battery pack within an inboard portion of a right wing. In a second specific example, the system includes a first battery pack within an inboard nacelle of a left wing and a second battery pack within an inboard nacelle of a right wing. Battery packs 702 may include a plurality of battery modules 706.

The energy storage system 700 includes a cooling system (e.g., fluid circulation system 704) that functions to circulate a working fluid within the battery pack 702 to remove heat generated by the battery pack 702 during operation or charging. Battery cells 708, battery module 706 and/or battery packs 702 can be fluidly connected by the cooling system in series and/or parallel in any suitable manner.

### Electrical Architecture for Aircraft

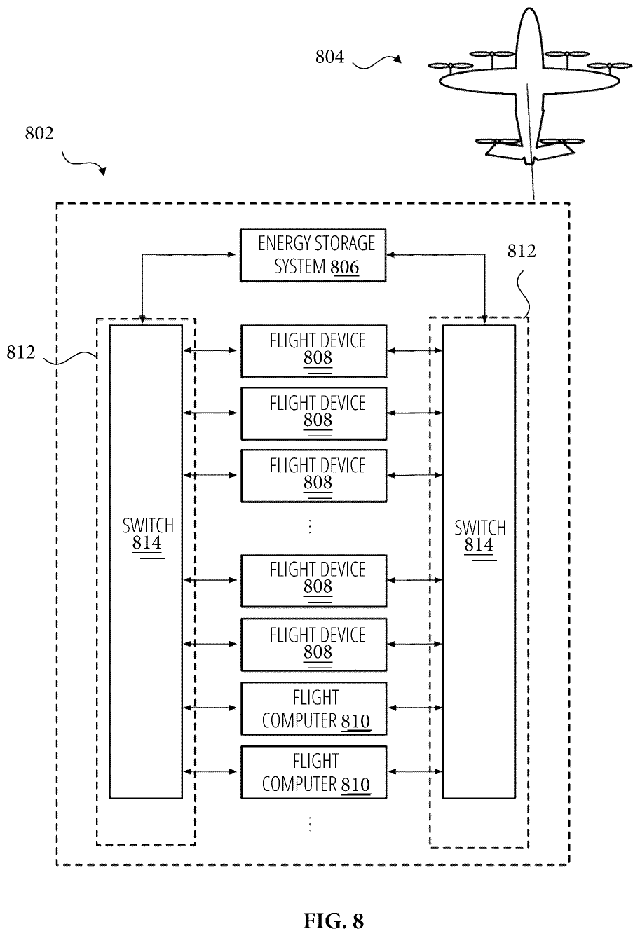

FIG. 8 illustrates some examples of an electrical architecture 802 for an aircraft 804. The electrical architecture 802 includes the energy storage system 806, multiple flight devices 808, multiple flight computers 810, and a distribution network 812. Network 812 includes several switches 814 and appropriate wired or wireless data-transmission links within the network 812 and with the other components of the electrical architecture 802.

The electrical architecture 802 functions to provide redundant and fault-tolerant power and data connections between the flight device 808, flight computer 810 and the energy storage system 806. The flight devices 808 can include any components related to aircraft flight, including, for example, actuators and control surfaces, such as ailerons, flaps, rudder fins, landing gear, sensors (e.g., kinematics sensors, such as IMUs; optical sensors, such as cameras; acoustic sensors, such as microphones and radar; temperature sensors; altimeters; pressure sensors; and/or any other suitable sensor), cabin systems, and so forth.

The flight computers 810 control the overall functioning of the aircraft 804, including interpreting and transforming flight data into commands that can be transmitted to and interpreted by controllable flight components. Data may be commands, aircraft state information, and/or any other appropriate data. Aircraft state information may include faults (fault indicator, fault status, fault status information, etc.); sensor readings or information collected by flight components such as speed, altitude, pressure, GPS information, acceleration, user control inputs (e.g., from a pilot or operator), measured motor RPM, radar, images, or other sensor data; component status (e.g., motor controller outputs, sensor status, on/off, etc.), energy storage system 806 state information (battery pack voltage, level of charge, temperature and so forth); and/or any other appropriate information. Commands may include faults (fault indicator, fault status, fault status information, etc.); control commands (e.g., commanding rotor RPM (or other related parameters such as torque, power, thrust, lift, etc.), data to be stored, commanding a wireless transmission, commanding display output, etc.); and/or any other appropriate information.

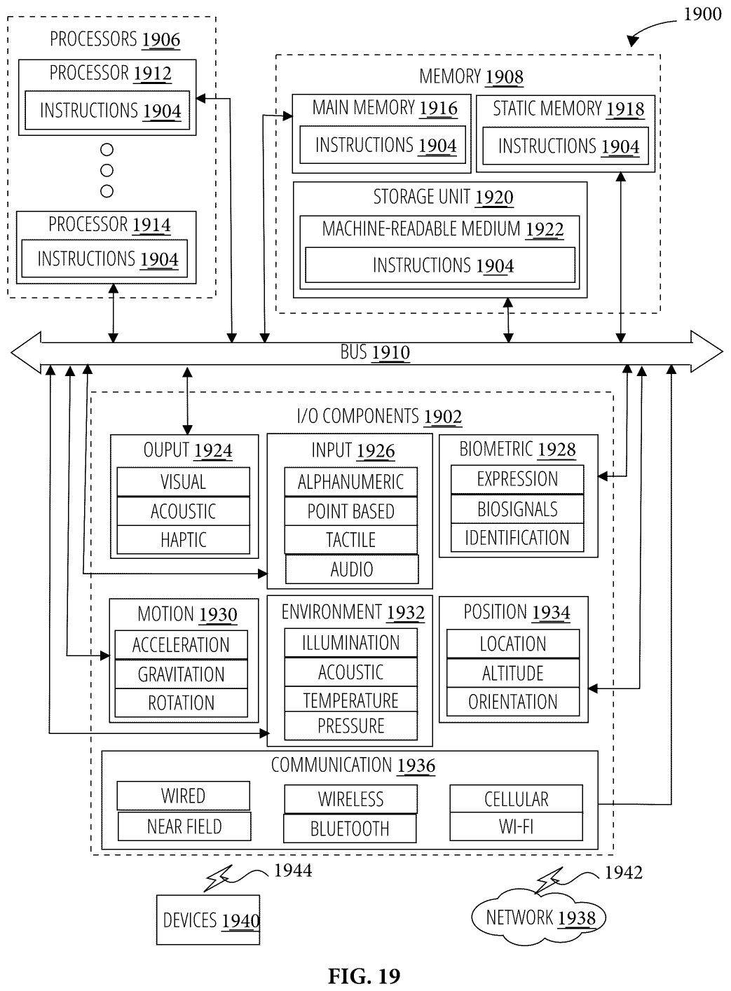

Included with the flight computers 810 are I/O components 1902 (shown in FIG. 19) used to receive input from and provide output to a pilot or other operator. I/O components 1902 may, for example, include a joystick, inceptor, or other flight control input device, data entry devices such as keyboards and touch-input devices, and one or more display screens for providing flight and other information to the pilot or other operator.

One or more of the flight computers 810 also perform the methods described below for determining the capabilities of the energy storage system 806, based on data received from the I/O components 1902, data entered by the pilot, data retrieved from one or more remote servers such as the data repository described below, as well as aircraft and battery state information.

### Detailed Examples

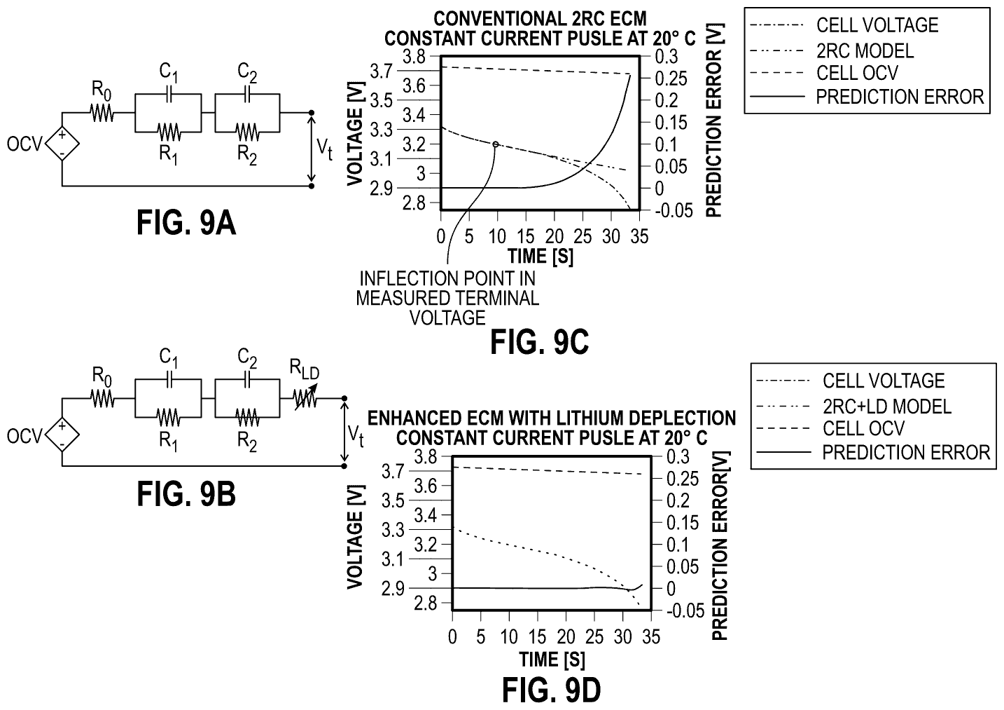

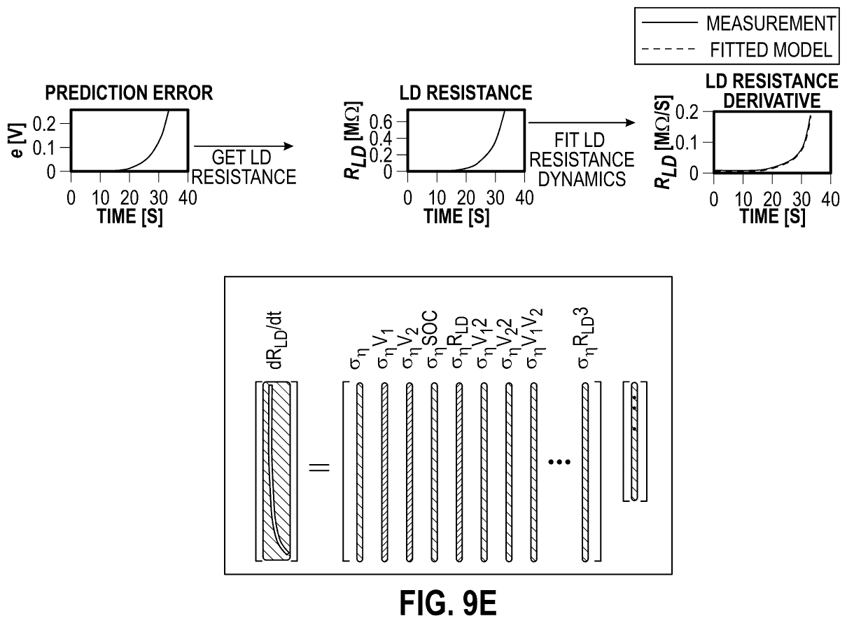

FIGS. 9-18 provide details, examples, and results of examples of the battery management system with enhanced ECM. The specifics provided within these examples are illustrative and not exhaustive. Different scenarios or applications might embody varying specifics, demonstrating the flexibility and broad applicability of the concepts discussed. These examples serve to clarify and exemplify the above content, but they are just a snapshot of potential applications and implementations. Further examples beyond those detailed below may vary in their specifics, depending on the context, the field of study, or the particular requirements of a project or application.

### Conventional ECM

In general, FIGS. 9(A) to 9(E) are graphical representations illustrating the enhanced equivalent circuit model for high current discharge of lithium-ion batteries with application to electric vertical takeoff and landing aircraft, according to some examples. FIG. 9(A) illustrates a traditional two resistor, two capacitor (2RC) ECM. This 2RC ECM is typically sufficient to capture 1 Hz dynamics inside a lithium-ion cell. The state and output equations for this 2RC ECM are given by:

$$\frac{dSOC}{d t} = \frac{I}{36 Q} \qquad ( 1 )$$

$$\frac{d {V}_{1}}{d t} = \frac{- {V}_{1}}{{τ}_{1}} + \frac{{IR}_{1}}{{τ}_{1}} \qquad ( 2 )$$

$$\frac{d {V}_{2}}{d t} = \frac{- {V}_{2}}{{τ}_{2}} + \frac{{IR}_{2}}{{τ}_{2}} \qquad ( 3 )$$

$${V}_{t , 2 RC} = O C V ( SOC , T ) + {V}_{1} + {V}_{2} + {IR}_{0} \qquad ( 4 )$$

where SOC is the cell state of charge in percent, I is the current (negative for discharge), Q is the cell capacity in Ampere hours, Vᵢ is the voltage across the i-th RC pair, τᵢ=RᵢCᵢ is the corresponding time constant, and OCV is the SOC and temperature dependent open-circuit voltage. Observed OCV hysteresis is minor in our selected cell, and therefore neglected for simplicity.

To highlight the shortcomings of this conventional 2RC ECM at capturing high-rate lithium depletion (LD) behavior, FIG. 9(C) illustrates an example high C-rate pulse data where the terminal voltage is concave as it approaches the lower limit of 2.75 V. Assuming (for illustration purposes only) constant circuit parameters through the relatively short pulse and recognizing the OCV in this region of SOC is nearly linear, it is apparent that this over-damped second order ECM will only predict convex voltage curves. An alternative model architecture is required to recreate such behavior.

### Discrepancy Modeling for Enhanced ECM

Discrepancy modeling seeks to identify a sparse dynamical system that can explain the observed prediction errors. This identified dynamical system is then added to the original model. Sparsity is a key feature to avoid overfitting and only finding the simplest model that can explain the observed behavior.

The method fits the prediction error derivative using the fewest terms from a library of regressors predefined by the user. For the ECM in consideration, this means finding a sparse representation for the right-hand side of the following equation:

$$\frac{d e}{d t} = f ( e , {V}_{1} , {V}_{2} , SOC , I )$$

where e denotes the prediction error. Having the right terms in the regressor library is helpful to successful application of the sparse regression framework. Indeed, an efficient representation may not be viable in the wrong coordinates. After exploring multiple avenues for finding the simplest model, at least three design choices can be made prior to applying the discrepancy modeling framework.

First, the observed error can be explained by a dynamic series resistance:

e=IR_{LD}

This assumption is derived from the observation that Li⁺ depletion leads to a sudden increase in ohmic resistance in the electrolyte phase. The electrolyte ionic conductivity is a function of Li⁺ concentration. As Li⁺ concentration goes to zero in the positive electrode domain under high C-rates, the electrolyte ohmic resistance increases accordingly. As the depletion region grows, so does the cell's ohmic resistance. This assumption is validated later when we measure the cell ohmic resistance for high current discharge pulses.

Second, the LD resistance growth has a triggering function, σ_{η}, driven by the total cell overpotential (V₁+V₂)

$${σ}_{η} = \frac{1}{2} [ 1 + tanh ( \frac{- ( {V}_{1} + {V}_{2} ) - {η}_{th}}{{δ}_{η}} ) ]$$

where ηₜₕ denotes the threshold overpotential above which LD growth is triggered and δ_{η} is a smoothing parameter determining the transition width for the sigmoid function (δ_{η}=4 mV throughout this document). The threshold overpotential can be approximated based on the total overpotential of the cell at the inflection point that is identified in FIG. 9(C). Finding the inflection point requires calculating the second derivative of the measured voltage, which makes it sensitive to measurement noise. In some examples, the method uses a total variation denoising algorithm to attenuate the noise before differentiation.

This function is designed to mimic the electrochemical behavior of the cell when approaching and exceeding the diffusion limited C-rate (DLC). The DLC depends on the initial Li⁺ concentration in the electrolyte, which in turn depends on the load history the cell has been subjected to. Therefore, the DLC at a given temperature and SOC could be lower in presence of concentration gradients compared to an equilibrium state. In the ECM, deviation from the equilibrium state is captured by the RC voltages (i.e., V₁ and V₂). Hence, the total predicted overpotential in the cell (η=−V₁−V₂) may be used as the activation signal.

Third, in some examples the method separates self-growth and forced growth terms. In other words, no cross terms are included between R_{LD} and the other independent variables (SOC, V₁, and V₂). This is solely to allow for more efficient model representation, as including the cross terms was found to lead to more complicated models without improved accuracy.

The LD resistance growth (error) dynamics can thus be written as:

$$\frac{d {R}_{L D}}{d t} = {σ}_{η} \times [ {f}_{1} ( {V}_{1} , {V}_{2} , SOC ) + {f}_{2} ( {R}_{L D} ) ] \qquad ( 5 )$$

where the first term on the right-hand side (f₁) determines the forced growth rate of the LD resistance, while the second term (f₂) governs its self-growth rate. Note that when starting from zero initial condition, LD resistance only starts growing when σ_{η} is activated. The sparse regression framework the is applied to identify the terms in f₁ and f₂. The method considers monomials of up to third degree, including cross terms between the input arguments of f₁. This yields the linear formulation:

$$\frac{d {R}_{L D}}{d t} = {σ}_{η} \times [ - {θ}_{η} ( {V}_{1} + {V}_{2} ) + {θ}_{R} {R}_{L D} ] \qquad ( 6 )$$

where θ_{η} and θ_{R} are the forced and self growth rate scalar parameters identified experimentally. To ensure monotonic behavior and avoid over-fitting, in some example the method forces both θ_{R} and θ_{η} to be non-negative. This means that the above equation leads to an unstable mode in the model to represent the observed voltage drop. However, the empirically observed phenomenon is reversible and the LD resistance relaxes upon a reduction in load. This is accommodated by further modifying the equation (6) as follows:

$$\frac{{dR}_{L D}}{dt} = {σ}_{η} \times [ - {θ}_{η} ( {V}_{1} + {V}_{2} ) + {θ}_{R} {R}_{L D} ] - ( 1 - {σ}_{η} ) \times \frac{{R}_{L D}}{{τ}_{L D}} \qquad ( 7 )$$

where τ_{LD} is the relaxation time constant for the LD resistance. The LD-ECM architecture is illustrated in FIG. 9(B) and the resulting fit to the same measurements is given in FIG. 9(D) showing significant improvement over the conventional 2RC ECM. The discrepancy modeling framework used to arrive at the above formulation is illustrated in FIG. 9(E).

Lastly, the addition of the LD resistance modifies the terminal voltage equation as follows:

$${V}_{t , LD - E C M} = O C V ( SOC , T ) + {V}_{1} + {V}_{2} + I \times ( {R}_{0} + {R}_{L D} ) \qquad ( 8 )$$

Compared to the conventional 2RC ECM, the LD-ECM has one additional dynamics state, i.e., R_{LD}, and three additional parameters, namely, ηₜₕ, θ_{η}, and θ_{R}, thereby allowing for a low dimensional representation of the observed LD behavior at high C-rates. Overall, the LD-ECM model can be represented in the simple state-space format as follows:

$$\frac{d}{dt} [ \begin{matrix}SOC \\ {V}_{1} \\ {V}_{2} \\ {R}_{L D}\end{matrix} ] = [ \begin{matrix}0 & 0 & 0 & 0 \\ 0 & \frac{- 1}{{τ}_{1}} & 0 & 0 \\ 0 & 0 & \frac{- 1}{{τ}_{2}} & 0 \\ 0 & - {σ}_{η} {θ}_{η} & - {σ}_{η} {θ}_{η} & {σ}_{η} {θ}_{R} - \frac{1 - {σ}_{η}}{{τ}_{LD}}\end{matrix} ] [ \begin{matrix}SOC \\ {V}_{1} \\ {V}_{2} \\ {R}_{L D}\end{matrix} ] + [ \begin{matrix}\frac{1}{36 Q} \\ \frac{{R}_{1}}{{τ}_{1}} \\ \frac{{R}_{2}}{{τ}_{2}} \\ 0\end{matrix} ] I \qquad ( 9 )$$

The compact state-space formulation simplifies use of the model for state estimation tasks. Nonetheless, the unstable eigenvalue of the system (recall that θ_{R}≥0) amplifies voltage sensitivity to parameter perturbations and makes parameter identification challenging.

### Model Parameterization

The enhanced ECM method, in some examples, adopts a linear parameter varying (LPV) approach to ECMs where each parameter is a function of SOC, temperature, and current. The current dependency is not desirable due to the additional dimensionality and the algebraic loop created by a load-dependent R₀ when power is the model input, but experimentation with removing the current dependency from all or some of the parameters resulted in significantly degraded model quality. The model parameters are thus given by:

$${θ}_{j , k} = {h}_{j} ( {SOC}_{k} , {T}_{k} , {I}_{k} , {α}_{j} ) \qquad ( 10 )$$

where θⱼ is the LD-ECM parameter of interest (either one of R₀, R₁, R₂, τ₁, τ₂, θ_{η}, θ_{R}, ηₜₕ), k is the time index, and hⱼ is the function representing the variations in parameter θⱼ, which is itself parameterized by αⱼ.

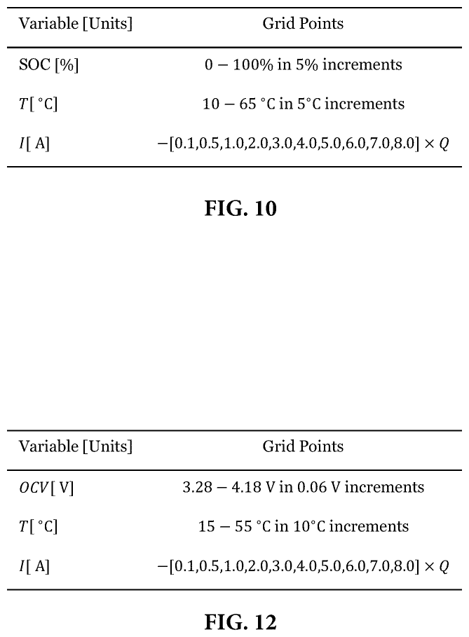

Some examples of the method use both lookup tables (LUT) with linear interpolation and functional representations for hⱼ's. By way of example, FIG. 10 is a table illustrating grid points for the discharge LUTs. For the LUT formulation, the method uses a uniform grid in all three dimensions, as shown in FIG. 10. For the functional representation, the method in some examples uses multivariate polynomials of varying degrees as well as rational functions.

In this formation, all θⱼ's are non-negative. This can be easily ensured in the LUT formulation, since each LUT entry can be specified directly. To satisfy the non-negativity requirement with the functional forms, some examples of the method use the sum-of-squares (SOS) polynomial representation:

θⱼ=Σⱼ(SOC,T,I,αⱼ)

where Σⱼ is the SOS polynomial representing parameter θⱼ. Constructing an SOS polynomial is straightforward when using quadratic forms; if z(x) is the vector of all monomials of x up to degree d, then Σ(x)=z^{T}(x)LL^{T}z(x) is an SOS polynomial of degree 2d, where L is any lower triangular matrix. A similar approach can be used for rational functions, where both the numerator and denominators are chosen to be SOS functions.

### Parameter Identification

### Characterization Test Design

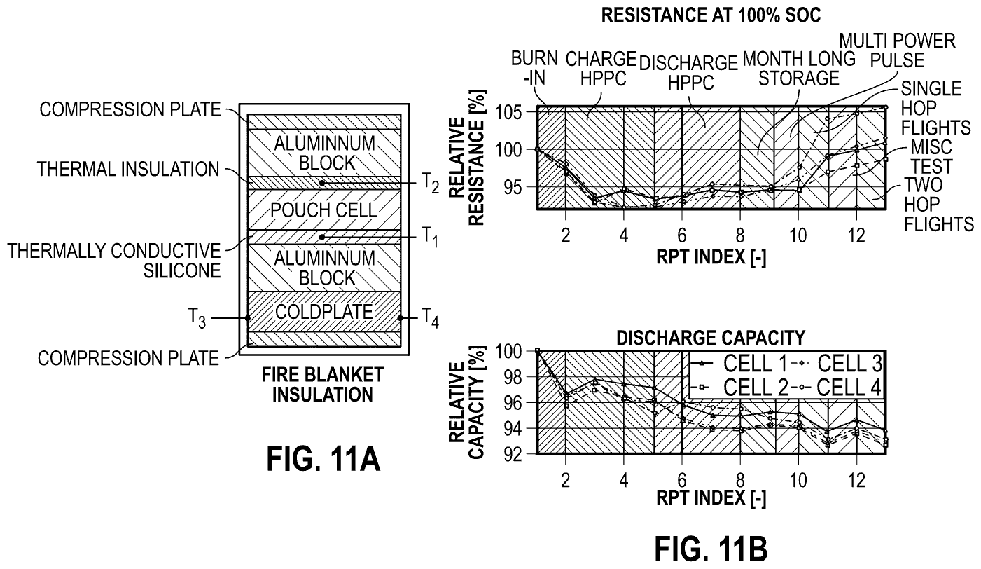

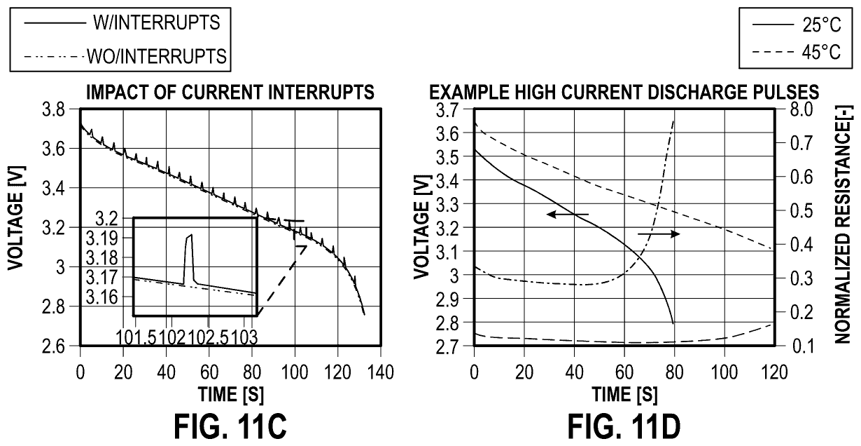

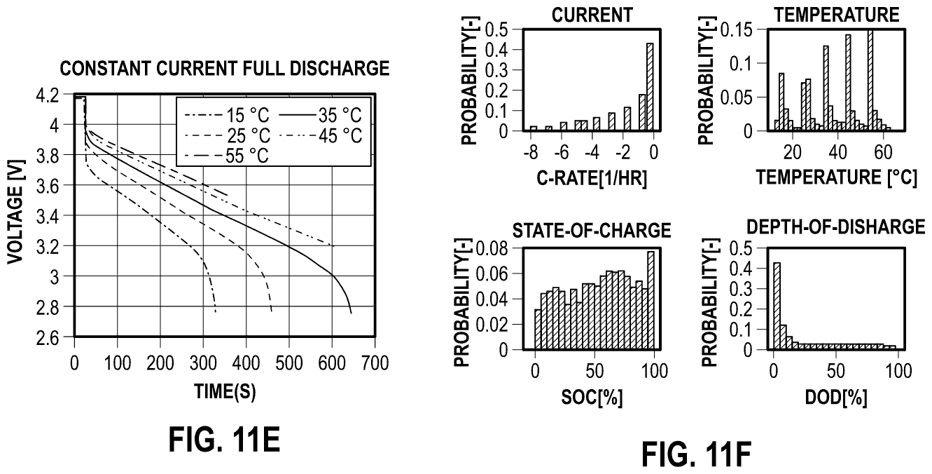

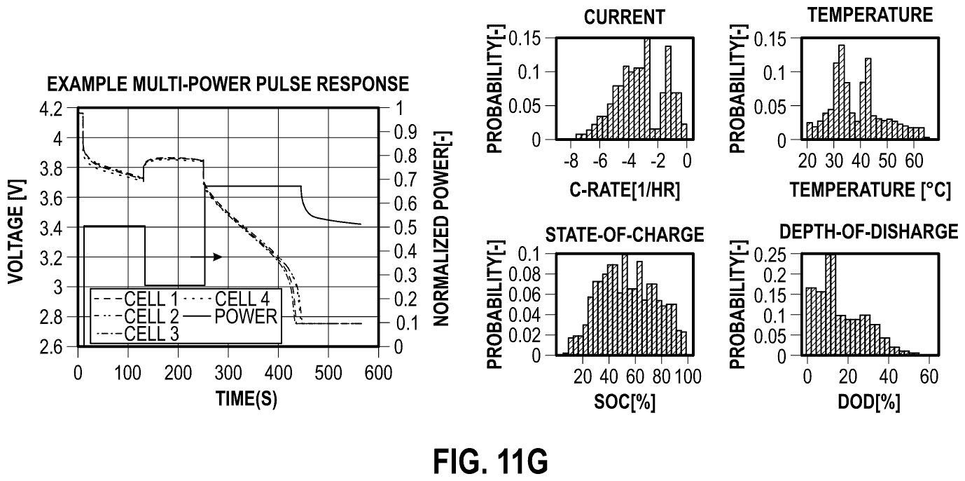

All test data were collected on large format commercial pouch cells with graphite negative and NMC positive electrode. Four cells from the same batch were used throughout the testing campaign. All tests were conducted in a blast chamber. FIG. 11(A) illustrates the test setup for obtaining the characterization test data for model evaluation. In particular, referring to FIG. 11(A), a fire blanket insulation temperature control was achieved by actively running temperature controlled coolant (de-ionized water) through a cold plate that mates one surface of the cell. The temperature reading T₂ was used as the cell temperature in all model evaluations.

All cells were initially cycled 110 times using a fast-charging protocol and a simplified eVTOL flight discharge profile that achieved a deep depth of discharge such that the cells were past their initial rapid degradation phase prior to characterization testing. The cells' state-of-health (SOH) was periodically checked using a standard reference performance test protocol (RPT) that included both capacity and resistance checks. FIG. 11(B) illustrates the annotated RPT results for the entire test campaign.

The first characterization test type was a set of constant current pulses (CCP) based on a full factorial design of experiment (DOE) with OCV (the proxy for SOC), temperature, and current as the experimental variables. FIG. 12 is a table illustrating the DOE for constant current pulse characterization (CCP). This DOE yielded a total of 800 CCP discharges. Each discharge pulse was 2 minutes long unless the cell hits the lower voltage limit of 2.75 V or an upper temperature limit of 65° C. Due to the large size of the DOE, each cell in the batch was used to cover a quarter of the design.

FIG. 11(C) illustrates a high C-rate CCP pulse showing minimal impact of current interrupts. Specifically, discharge pulses at and above 5C included small current interrupts of −0.2C magnitude for a duration of 0.2 seconds every 5 seconds to directly measure the change in ohmic resistance of the cell throughout the pulse. FIG. 11(C) also illustrates the near identical performance of the same cell tested to this high current pulse without the interrupts. Thus, once the ohmic resistance was estimated for each pulse, the impact of interrupts was removed from the voltage data to ensure data integrity when down-sampled to 1 second intervals for fitting.

FIG. 11(D) illustrates example high C-rate discharge pulses and their corresponding resistance estimated with the interrupt method. More specifically, FIG. 11(D) shows two high C-rate CCP pulses at 25 and 45° C. and the corresponding resistances measured using the current interrupts. The voltage curves shown have been processed as noted above to remove the effect of the interrupts. While both pulses start at ˜67% SOC, only the 25° C. exhibits the accelerated voltage decay that is the sign of LD and a corresponding exponential increase in ohmic resistance. The measured resistance of 45° C. pulse remains nearly constant. This serves as an empirical confirmation of the assumption that LD exhibits an increase in a cell's ohmic resistance.

The second characterization test type is a set of full discharge (FD) constant current pulses from top of charge to the minimum voltage. FIG. 11(E) illustrates an example data set of full discharge data at different temperatures for a single C-rate. These tests were conducted at the same temperatures as in the CCP set, but only for C-rates up to 6 C.

FIG. 11(F) illustrates histograms of data coverage for all constant current (CCP and FD) tests. While the CCP and FD data sets provide good coverage of the SOC, temperature, and current conditions, as shown in FIG. 11(F), they are all constant current and always start from rest. Therefore, a third characterization test was introduced. This test type is a multi-power pulse (MPP) consisting of three sequential 2-minute long constant power discharges. A test was terminated immediately if a temperature limit was encountered; if a voltage limit is encountered, discharge continued in a constant voltage operating mode. Power magnitudes were ordered medium, low, high and a total of 72 tests were conducted at temperatures of 20, 30, and 40° C. FIG. 11(G) illustrates a MPP example and data coverage histograms. A sample profile and the resulting voltage response is shown in FIG. 11(G). Data coverage histograms for the MPP tests are also provided in FIG. 11(G).

### Identification Problem Formulation

### Solution Strategy

To map out parameter dependencies on operating conditions, often short pulses are used to identify ECM parameters at each SOC and temperature condition. The results are then utilized to fit constant model parameter at the specified conditions. This approach is appealing for its computational efficiency in the identification step, since each pulse can be fitted individually by solving a small optimization problem. Unfortunately, the constant parameter assumption breaks down for longer pulses or those at higher C-rates since the SOC and temperature can vary meaningfully even within a 60 second time window. In some examples, this issue is circumvented by using subspace methods. In this case, the focus is on identifying the full parameter function in one optimization using the entire characterization data set.

The large size of the data set and the high dimensional parameter space results in a large-scale optimization problem. To simplify the process, in some examples the method first fits one separate parameter set to the CCP and FD data at each individual current level, reducing the number of decision variables in a single optimization problem by a factor of ten. Subsequently, the complete large scale optimization problem over all CCP, FD, and MPP data is conducted using the previous result as an initial guess.

### Optimization Formulation

The parameter identification step seeks to find the α vector for ECM parameters that best fits the characterization data. This is formulated as:

$$\begin{matrix}{min}_{α} & {J}_{e r r} ( α ) + {J}_{r e g} ( α ) \\ s . t . & \underline{α} \leq α \leq \overline{α}\end{matrix} \qquad ( 11 )$$

where α=α_{R}_{₀}, α_{R}_{₁}, α_{R}_{₂}, α_{τ}_{₁}, α_{τ}_{₂}, α_{θ}_{_{η}}, α_{θ}_{_{R}}, α_{η}_{ₜₕ}] is the vector of decision variables, Jₑᵣᵣ (α) and J_{reg} (α) are the prediction error and the regularization costs, respectively, while α and α̅ denote the parameter lower and upper bounds that are selected based on cell testing data. The bounds are also used to enforce a sufficient time scale separation between the two RC pairs (1.5 s≤τ₁≤10 s, 30 s≤τ₂≤150 s) to improve identifiability.

The prediction error cost in Eq. 11 is given by:

$${J}_{err} ( α ) = {\sum }_{i = 1}^{{n}_{pulse}} [ \frac{{w}_{1}}{{η}_{scale}} R M S {E}_{L D + RC , i} ( α ) + \frac{{w}_{2}}{{η}_{scale}} {RMSE}_{diff , i} ( α ) + \frac{{w}_{3}}{{η}_{scale}} {E}_{L D + R C , {n}_{t} , i} ( α ) + {w}_{4} R M S {E}_{{R}_{ohm} , i} ( α ) + \frac{{w}_{5}}{{η}_{scale}} R M S {E}_{R C , i} ( α ) + \qquad ( 12 )$$

All terms are evaluated individually for each pulse at a given current and the summation over all pulses is used in the objective function. The first term is the root mean squared error (RMSE) of the model. The second term is the RMSE of the voltage prediction error derivative and is used to force the predicted voltage curvature to match the measurements more closely. The third term additionally penalizes deviations in the last data point in each pulse, where the subscript nₜ is used to denote the last index in the pulse. This term is added to better match the time to min voltage, since that is an important criterion for available energy and power predictions. The fourth term is the RMSE of the ohmic resistance prediction error. Note that the predicted ohmic resistance in the model is R_{ohm,model}=R₀+R_{LD} and ohmic resistance measurements are only available in the high C-rate pulse of the CCP data set. Hence, this term is set to zero when the measurements are not available. The fifth term is the RMSE of only the 2RC portion of the model (i.e., without LD resistance). This term is added to discourage the optimizer to use the LD resistance when the RC portion of the model is sufficient to fit the data. The last term penalizes the value of the LD resistance at the end of the pulse and serves as an additional guardrail against over-reliance on the LD term.

In some examples, some of the weights are divided by η_{scale}. This is a scaling factor that is equal to the average of measured overpotentials over all the pulses at a given C-rate. This is done to balance the error and regularization costs equally at different C-rates (since the overpotential will be smaller at lower currents and the error cost can be overwhelmed by the regularization cost without appropriate scaling). Lastly, all wᵢ's except for w₅ are constants. w₅ is a time varying function defined separately for each pulse.

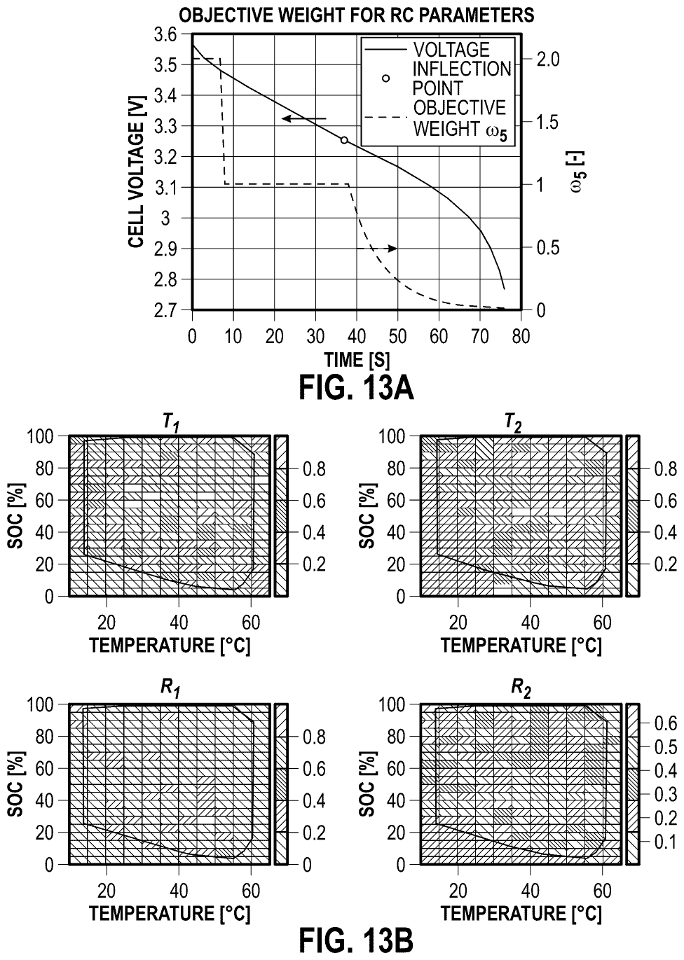

FIG. 13(A) illustrates creating the cost function for parameter identification using the variable weight for RC-only error. An example time profile of w₅ is shown in FIG. 13(A), where it is seen to have three distinct regions; for the first 8 seconds, w₅ is given a higher value to deal with the data imbalance between the fast and slow dynamics. Subsequently, w₅ goes through a flat region, before starting an exponential decay. The final decaying behavior is added to allow the RC portion of the model to deviate from the measurements past an inflection point, when one exists. This helps the optimizer to not bias the RC parameters to fit the LD behavior.

### Parameter Regularization: LUT

With constant current characterization data, the LUTs can be built one current at a time. At a fixed current, each LUT has 252 grid points, leaving a total of 2016 decision variables for all 8 LD-ECM parameters (i.e., α∈ [symbol] ^{2016×1}). Because of this over-parameterized representation, care must be taken to ensure smoothness of the resulting LUTs and limit use of the LD resistance term where two RC pairs alone can sufficiently match the measurements. Indeed, attempts at fitting the model without regularization guardrails resulted in accurate predictions on the training data. However, the resulting LUTs lacked smoothness and led to large errors on the validation data sets. This is shown in FIG. 13(B). FIG. 13(B) illustrates example LUT results obtained with zero regularization, where the black boundary indicates the convex hull of the test data coverage in this example fitting case.

Thus, the following LUT regularization cost was developed:

$${J}_{reg} ( α ) = {\sum }_{j ∈ \{ {R}_{0} , {R}_{1} , {R}_{2} , {τ}_{1} , {τ}_{2} , {θ}_{η} , {θ}_{R ,} {η}_{th} \}} [ {w}_{reg , 1 , j} ( {‖ {Δ}_{T} {α}_{j} ‖}_{2}^{2} + {‖ {Δ}_{SOC} {α}_{j} ‖}_{2}^{2} ) + {w}_{r eg , 2 , j} ( {‖ {Δ}_{T}^{2} {α}_{j} ‖}_{2}^{2} + {‖ {Δ}_{SOC}^{2} {α}_{j} ‖}_{2}^{2} ) + {w}_{reg , I , 1 , j} ( {‖ {Δ}_{I} {α}_{j} ‖}_{2}^{2} ) ] + \qquad ( 13 )$$

where the Δᵢ operator is a difference operator applied in the i-th variable direction (to approximate the first derivative), Δᵢ² denotes two consecutive applications of the operator in the respective direction (to approximate the second derivative), ∥⋅∥ₖ is the usual k-th norm. The arguments inside the summation are penalizing the first and second derivatives of the parameters in both the SOC and temperature directions and the first derivative along the current direction. This ensures smoothness of the resulting parameter tables at a given current, and slowly varying parameters between different current levels. When fitting the LUTs, some examples start at the highest C-rate where the current regularization term is set to zero. For each subsequently lower C-rate fitting, the LUT values are regularized against their corresponding values identified at the previous current. Additional terms penalize the l-norm of the LD parameters. This is done to minimize LD usage to only necessary conditions. Also, it should be noted that all the weights are positive quantities. Therefore, the above formulation forces ηₜₕ to be as high as possible, which has the effect of delaying the onset of LD, thereby minimizing its occurrence. A similar penalty is applied to τ₂ (the bigger time constant in our model) to favor better matching the longer-term behavior, when only shorter duration pulses are available for certain conditions (due to hitting a cell operational limit before the 2 minute pulse duration is over).

### Parameter Regularization: Functional Representation

Given inherent smoothness in polynomial and rational representations, the regularization cost for functional forms can be simplified:

$${J}_{r e g} ( α ) = {w}_{{θ}_{η}} {‖ {θ}_{η} ‖}_{1} + {w}_{{θ}_{R}} {‖ {θ}_{R} ‖}_{1} - {w}_{{η}_{t h}} {‖ {η}_{t h} ‖}_{1} - {w}_{{τ}_{2}} {‖ {τ}_{2} ‖}_{1} + {w}_{r e g} {‖ α ‖}_{2} + {w}_{c onstraint} {‖ C ‖}_{1} \qquad ( 14 )$$

where the first four terms on the right hand side are identical to those in equation (13), the fifth term is a 2norm regularization on the coefficient of the function used in fitting, and the last term is the penalty for enforcing soft constraints on parameter upper bounds. The use of SOS polynomials allows for enforcing the lower bounds by construction (by simply adding the lower bound to the SOS polynomial). This ensures the critical lower bounds that are required for solver stability are never violated. The upper bounds are less critical for numerical solver stability and are implemented as soft constraints through a penalty method via leveraging a linear penalty term with a sigmoid activation on parameter values normalized to the unit interval:

$${C}_{j} = {\sum }_{i} 0.5 [ 1 + tanh ( \frac{{θ}_{i , normalized} - 1}{1 {0}^{- 3}} ) ] {θ}_{i , normalized} \qquad ( 15 )$$

### Numerical Optimization

For model training, the LD-ECM model is integrated using a forward Euler integration method with the time step of 1 second. Model integration was done using CasADi in Matlab to utilize its automatic differentiation for Hessian computations. For CCP fitting, a direct single shooting approach was used, where the entire trajectory was simulated in a recursive fashion and no additional decision variables were added to the original problem. However, for the FD data set the length of the voltage sequence can exceed 3000 (e.g., for 1C discharge sampled at 1 second). For such long sequences, the Hessian expressions can become very cumbersome. Therefore, some examples used a partially constrained multiple shooting approach, where a long trajectory was broken into 2-minute segments and additional decision variables for states at the segmentation points were introduced.

Constraints were also added to ensure state continuity at those points. This approach reduces the recursion length in each single shooting segment and simplifies the expressions in the Hessian. The resulting optimization problem in equation (11) is then solved using IPOPT with MA27 from the HSL libraries as the linear solver. In all cases, when fitting to constant current data at only one C-rate, the exact Hessian was used (as provided by CasADi). However, when fitting to the variable current MPP data set, the L-BFGS approximation is used for the Hessian. For LUT fitting, some examples start the highest C-rate pulse fitting with a uniform initial guess. But for subsequently lower C-rate pulses, the examples use the previous slice of the LUT to warm start the optimization. When fitting the SOS functional forms, the examples warm start the optimization by initially fitting the function coefficients to the LUT data.

### Model Fitting Results

Lookup Tables vs. Functional Forms: Comparison of Fit Quality on CCP Data

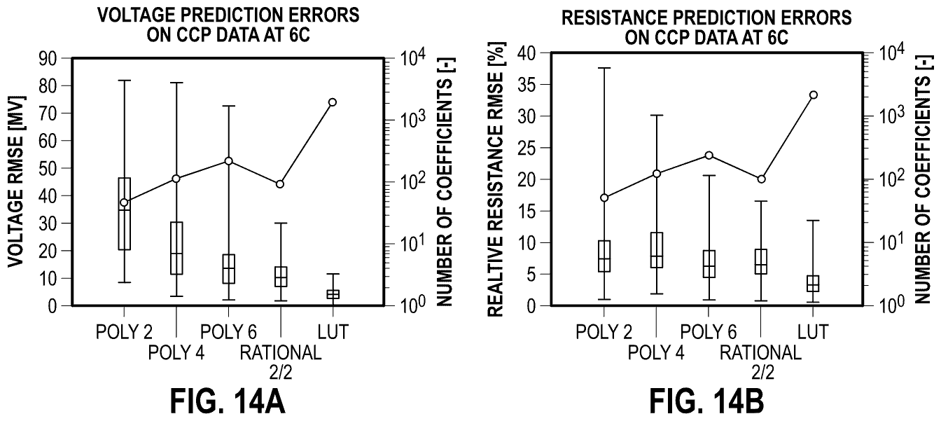

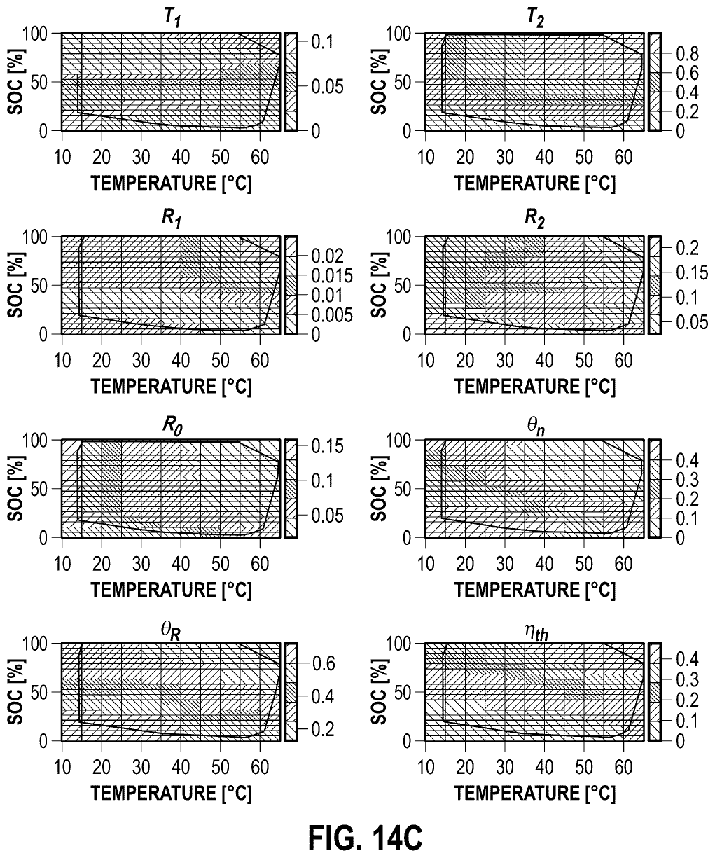

FIG. 14(A) and FIG. 14(B) illustrate a comparison between the voltage and resistance fit qualities obtained on 6C discharge CCP data with LUT and different functional form representation. Specifically, FIG. 14(A) illustrates the performance of examples of the enhanced ECM model on training data and the RMSE on 6C CCP data with different parameter representations. FIG. 14(B) illustrates the performance of examples of the enhanced ECM model on training data and 6C pulses at two temperatures with the corresponding ohmic resistance.

Referring to FIGS. 14(A) and 14(B), it can be seen that the LUT provides the best overall fits. This is not surprising given that the LUT is much more expressive than the functional form and has up to two orders of magnitude more degrees of freedom. Among the functional representations, the average RMSE declines with the polynomial degree, as the representation becomes more expressive. The rational functions clearly outperform the polynomials, as a rational function with quadratic numerator and denominator (12 variables per LD-ECM parameter and 96 total parameters) achieves training errors on par with the LUT.

The functional forms are often harder to fit; each parameter in the functional form representation can impact all data, whereas the impact of a parameter in the LUT is restricted to a small region around its corresponding grid points. This also has an implication for updating the model with new data. Specifically, when new data are to be considered with the LUT approach, only the LUT entries can be updated corresponding to the conditions observed in the new data. This contrasts with the functional form approach, where changing any coefficient in the function impacts the function output everywhere in its domain.

Fitting a given C-rate from the CCP data usually takes around 5-10 minutes for both the LUT and the low-order polynomials and rational functions. Higher order functions can take significantly longer. While the LUT formulation results in up to two orders of magnitude more decision variables, the resulting Hessian structure is very sparse and the problem can be solved efficiently, whereas the functional form representation results in a dense Hessian. Hence, the solution times for the LUT approach is favorable on bigger data sets or those that contain longer sequences. For these reasons and its better expressive power, some examples of the method use the LUT method, which will be discussed in the remainder of this disclosure.

### Parameter LUTs and Performance on CCP, FD, and MPP

FIG. 14(C) illustrates exemplary parameter LUTs at 6C discharge current. These are fitted normalized lookup tables to 6C CCP data where the black boundaries denote the convex hull of the CCP data coverage. Overall, the resulting parameter tables are sufficiently smooth thanks to the regularization terms in the objective function. The resistance tables R₀ and R₂ follow the expected trend of decreasing with temperature. The trends in the LD parameters follow intuition as well: it is expected that the LD is more pronounced at lower SOC and lower temperatures, where diffusion processes within the cell are slower. Indeed, the identified ηₜₕ diminishes as one moves towards lower SOC and temperatures, expediting the onset of LD. Similarly, both growth parameters. θ_{R} and θ_{η}, are larger in the same region, indicating faster LD resistance growth.

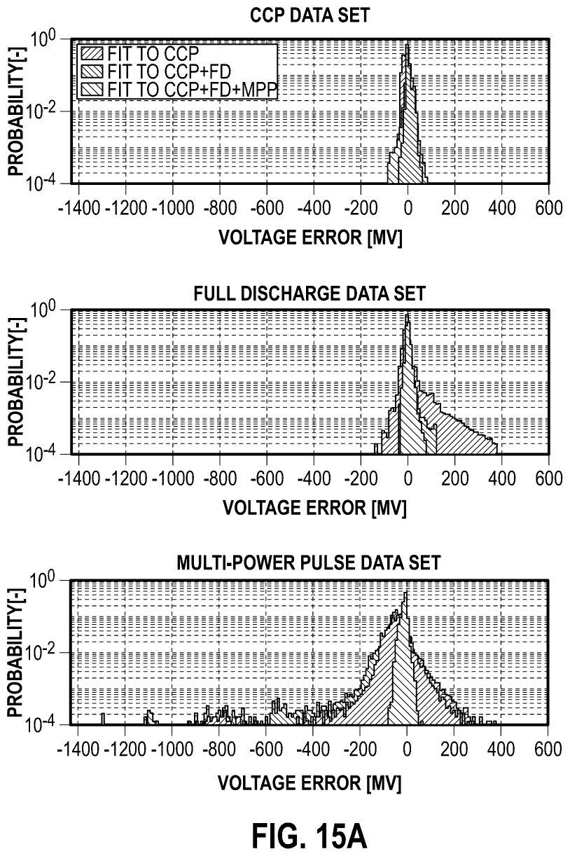

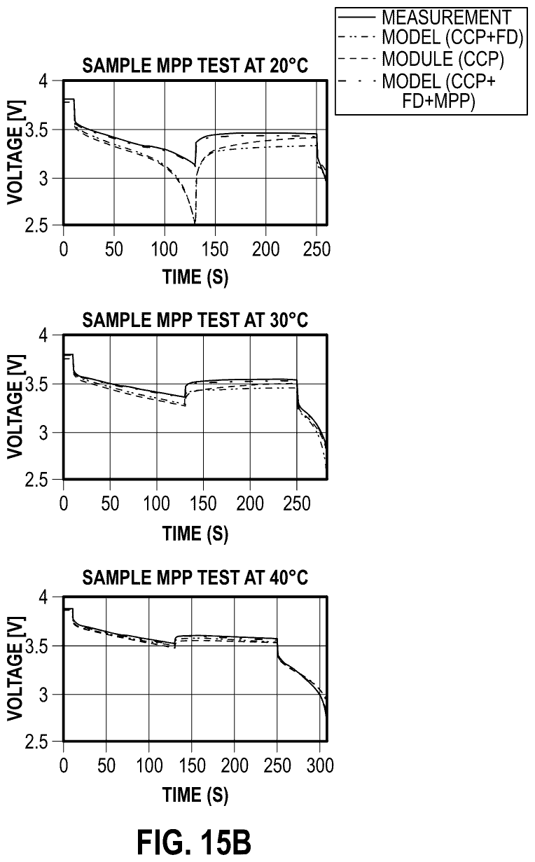

The LUT model performance was also evaluated on the characterization data when fitted with progressively more data. FIG. 15(A) illustrates the impact of a fine-tuning step and shows the voltage prediction error histograms before and after the fine tuning. It should be noted that the y-axis is in logarithmic scale to better reveal the distribution tails. FIG. 15(A) illustrates the performance of 3 versions of the LUT model that are fitted using (1) CCP data only, (2) CCP and FD data, and (3) all characterization data (CCP, FD, and MPP). The results indicate that the model trained on CCP data does not generalize very well to deeper discharges seen in the FD data set, nor to the variable current MPP. Similarly, the model does not perform well on the variable current MPP data, when trained on only constant current CCP and FD data sets. This highlights that the CCP data set, commonly used in literature for ECM parameter identification, may not be informative enough for high C-rate regimes. Moreover, this observation confirms that the MPP data set indeed contains information that is new for a model built on CCP and FD data sets.

FIG. 15(B) illustrates the impact of fine-tuning step and shows example MPP profiles and the fit quality before and after the fine tuning step. FIG. 15(B) shows the model predictions on some MPP examples for the 3 different model versions, confirming the superior performance by the model trained on all characterization data.

### Model Validation

### Validation Metric

Typically, validation of battery models focus on accuracy of predicted voltage. While this can be useful to battery modelers and engineers designing hardware and algorithms, it is not directly relevant to the assessment of flight safety. The Federal Aviation Administration's traditional mandate is that every flight plan include a fuel reserve above and beyond what is necessary to reach the intended destination, expressed in terms of time. Therefore, the critical metric for evaluating battery model performance in eVTOL applications is reserve time prediction accuracy.

Official requirements and associated conditions for eVTOL reserves, as well as indication accuracies, currently are still under development. Regardless, it is expected that the most challenging reserve prediction task will be predicting at-destination hover reserve during pre-flight planning. This has the longest time horizon and the most challenging, highest power reserve condition. This prediction task can be used for validation of model performance herein. To this end, some examples include an extra segment of constant power discharge at the end of each battery power profile to represent the available hover reserve. It is continued until the cell reaches a maximum temperature or minimum voltage limit, and the measured duration is compared to the model predicted duration. In some examples, the distribution of the differences between these two values define the model quality.

### Validation Test Design

The validation test includes a suite of eVTOL flight profiles encompassing a wide array of conditions within the operational envelope. Specifically, there were designed both one- and two-hop profiles. In a one-hop profile, the vehicle takes off and travels to destination with no stops in between, while a two-hop profile contains two back-to-back flights, with a short rest period of 3 minutes and no charging in between. For each flight, the test set includes several of the following possible variants.

A first variant is a Nominal variant. This means that no faults occur during the flight. A second variant is a One Engine Inoperable Landing (OEI Landing) variant. This variant is a fault case where a single propulsion unit is rendered inoperable at the end of cruise, putting more load on the remaining units, and thereby increasing the power drawn from all battery packs through the descent, transition, and hover landing. A third variant is a Battery Out Landing (BO Landing) variant. This is a fault case where one battery pack is rendered inoperable at the end of cruise, increasing the power drawn from the remaining battery packs through the descent, transition, and hover landing.

A fourth variant is a One Engine Inoperable Launch-Abort (OEI Launch-Abort) variant. This is a fault case where a propulsion unit is rendered inoperable during takeoff, increasing the power drawn from all battery packs through the rest of the flight including cruise, descent, transition, and hover landing. The cruise altitude and speed are significantly decreased, and the cruise duration is shortened to near zero. A fifth variant is a Battery Out Launch-Abort (BO Launch-Abort) variant. This is a fault case where a single battery pack is rendered inoperable during takeoff, increasing the power drawn from remaining battery packs through the rest of the flight including cruise, descent, transition, and hover landing. The cruise altitude and speed are significantly decreased, and the cruise duration is shortened to near zero.

The vehicle loads were varied across flights, such as ambient temperature (which affects propulsion unit power) and vehicle gross takeoff weight. The tests also examined various battery initial conditions including temperature and SOC. The tests generated battery power profiles tailored to each combination of flight profiles and test conditions. Variations in cruise distance, subject to the constraint of a positive reserve duration, were then included in the validation test set. Overall, this validation set includes a total of 116 one-hop and 49 two-hop flight profiles, each with four replicates.

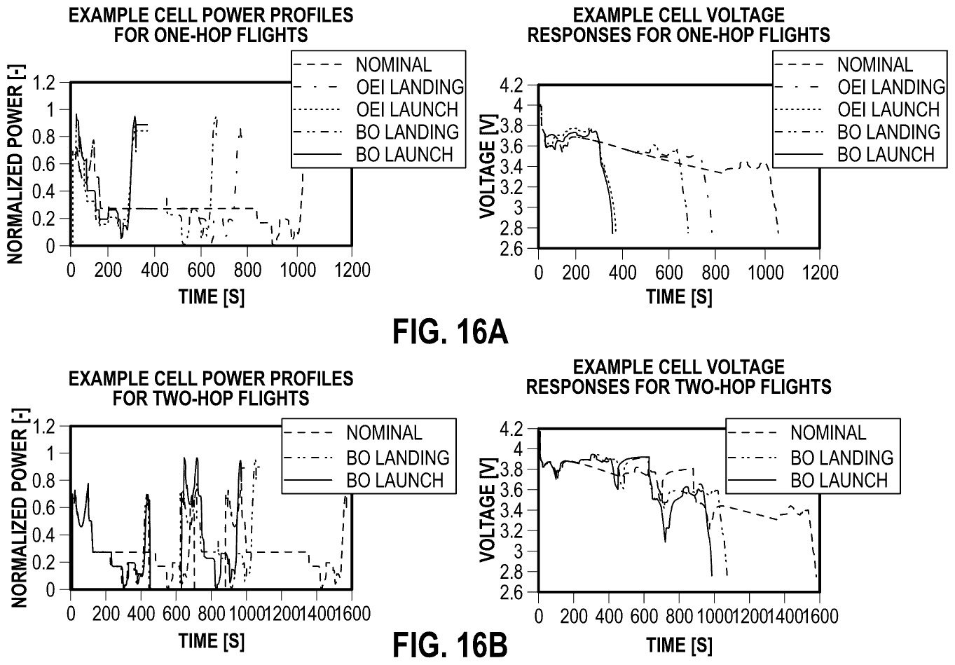

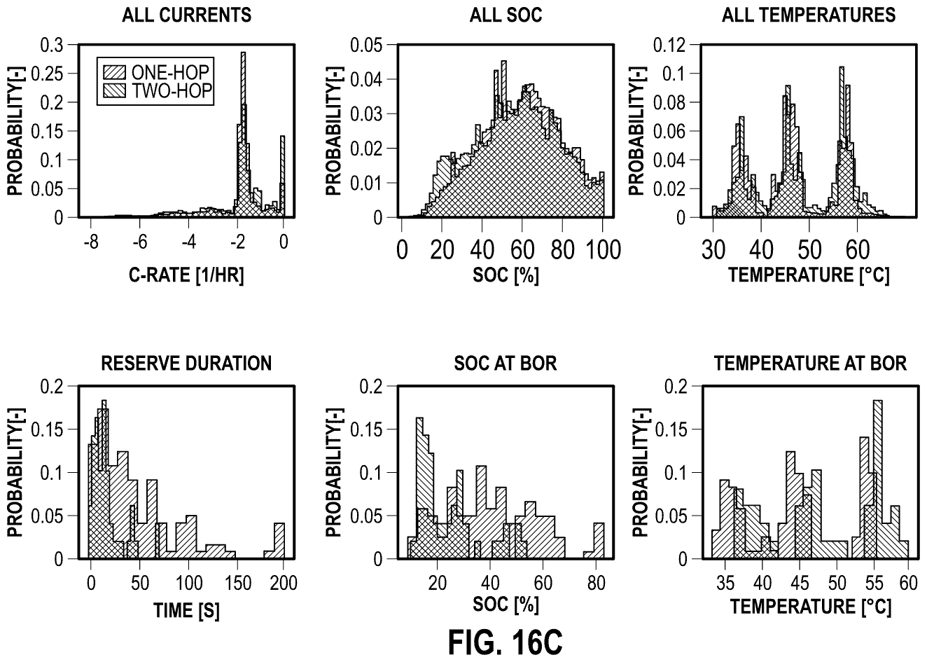

Distributions of key metrics on tested power profiles and the battery conditions at beginning-of-reserve (BOR) are given in FIGS. 16(A), 16(B), and 16(C). FIG. 16(A) illustrates a validation flight data set including example power profiles and corresponding cell voltage response for one-hop missions with the five different variants. FIG. 16(B) illustrates a validation flight data set including example power profiles and corresponding cell voltage response for two-hop missions with three different variants. The remaining variants are omitted to avoid clutter. And FIG. 16(C) illustrates a validation flight data set including the distributions of key metrics through entire flights as well as at the beginning of reserve section for one- and two-hop flights.

### Model Performance on Validation Data

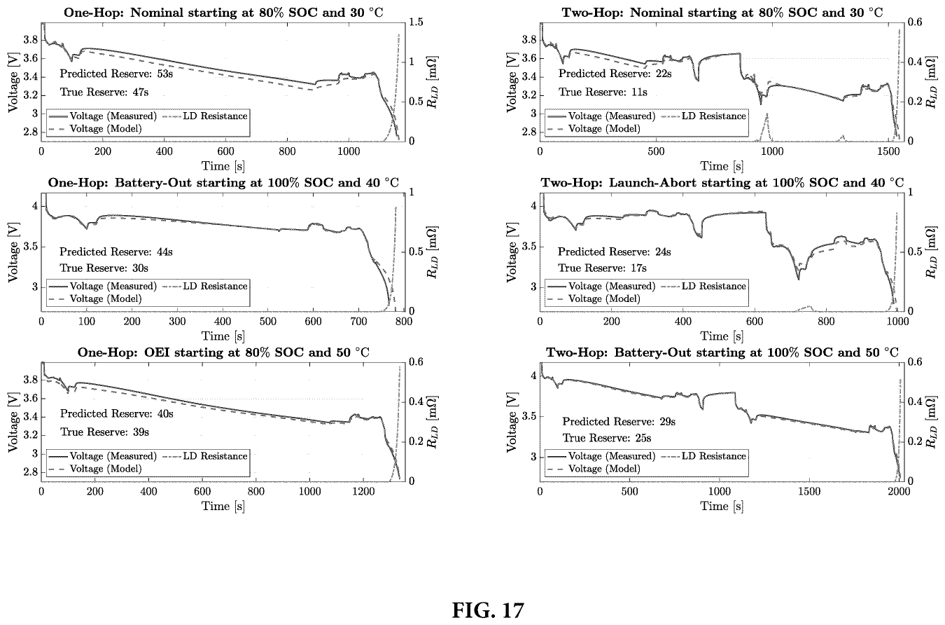

FIG. 17 illustrates the performance of some examples of the enhanced ECM model on several one- and two-hop flights in the validation data set. As shown in FIG. 17, these examples are from one- and two-hop flight data sets at different temperatures along with the corresponding model predictions and the predicted and true reserves for each example. Overall, the examples show a good match between the model and measurements, and the reserve prediction errors are small to moderate in most cases. However, in some cases errors of 100 mV and greater can be observed. This error can be partially attributed to the fact that aging is accounted for by uniformly increasing the resistance parameters across all conditions based on an RPT resistance estimate that is calculated from a 4C pulse at 40° C. However, the parameters are expected to have changed to a variable degree at different conditions. This in turn highlights the challenge of accounting for aging in LPV ECM formulations. Optimal experimental design methods may be used to address this challenge.

FIG. 17 also illustrates the LD resistance values. The LD resistance is only activated under high load scenarios, as intended. This means that in most one-hop flights, the LD resistance only starts to grow near or during the hover reserve at the end of the mission. For some two-hop flights on the other hand, the cell can approach DLC during the takeoff for the second of the two back-to-back flights, where the takeoff SOC is lower due to lack of charging after the first flight.

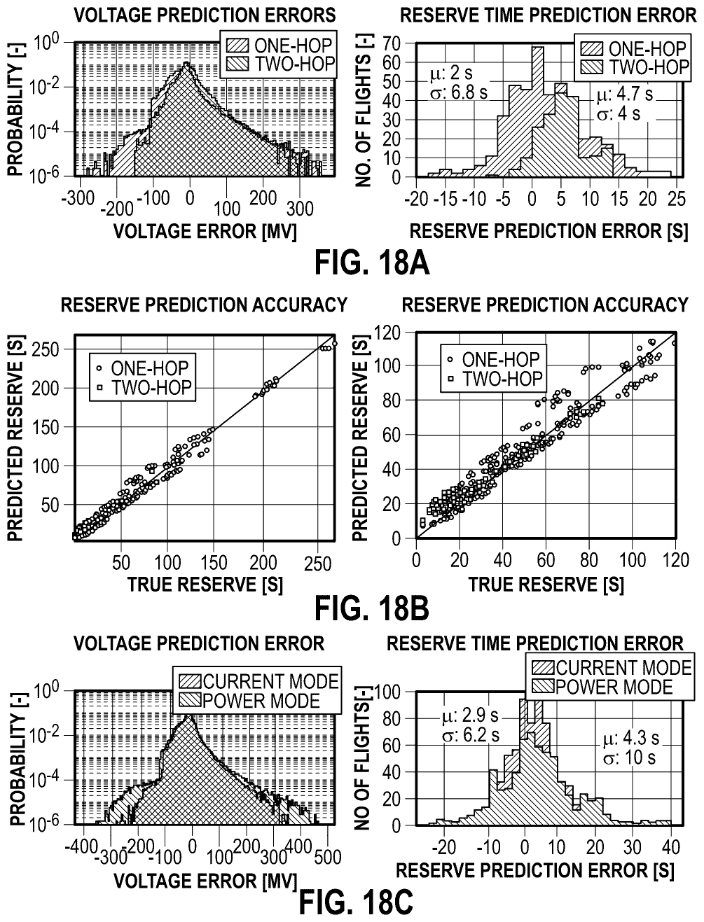

More comprehensive model prediction error statistics are presented in FIGS. 18(A), 18(B), and 18(C). FIG. 18(A) illustrates the error statistics on all replicates of validation flights including voltage and reserve time prediction error distributions for one- and two-hop flights. Specifically, the voltage and reserve prediction error distributions for all replicates of one- and two-hop flights are shown in FIG. 18(A), where a positive error indicates model over-prediction. For both sets of flight data, the model voltage error distribution has a slightly longer tail to the right and the reserve prediction errors have a positive mean, indicating a tendency to over-predict the reserve capability. While better accounting for cell aging is expected to improve these statistics, battery algorithms that rely on such a model to estimate the state-of-energy or power (SOE/SOP) can apply a threshold to the prediction to move the distribution to the left and ensure conservative predictions.

FIG. 18(B) illustrates error statistics on all replicates of validation flights including predicted vs. true reserve values. An exploded version is also provided to better highlight the data with true reserve less than 2 minutes. A closer look at the reserve prediction errors is provided in FIG. 18(B) where a zoomed in version is also shown, highlighting the cases in the data set with less than 2 minutes of true reserve. These cases are more critical, as they are closer to the expected true reserve requirements. The results overall show a good agreement between the model and the measurements. Nonetheless, a slight over-prediction of reserve capability is again observable in this view, especially for the two-hop cases, highlighting the need to better account for aging.

Finally, it should be noted that throughout the model fitting and validation processes so far, measured current has been used as an input for the model. However, in application, predictions are often made using requested power as input. Examples of the enhanced ECM model can easily be iterated over to find the current that matches the requested power. However, the process is expected to amplify the model error. To quantify that, FIG. 18(C) illustrates a comparison of voltage and reserve time prediction error distributions for all flights obtained by running the model in current and power modes. In other words, the model prediction error distributions are compared for voltage and reserve capability under both current and power mode simulations. The figure includes data from all replicates of one- and two-hop flights. As expected, running the model in power mode results in longer tails for the voltage prediction errors. Similarly, the mean of the reserve prediction error distribution is shifted further to the right. Overall, these results indicate that accurately capturing a battery cell response in a lithium depleted region can be very challenging. This is because the voltage sensitivity to small parameter perturbations grows significantly as the cell gets closer to the DLC. Examples of the enhanced ECM model have been shown to achieves good accuracy on this task.

### Summary and Conclusions

The requirements of eVTOL applications lead to challenging conditions for the battery packs, including high discharge rates at low SOCs encountered in fault scenarios. Examples of the enhanced ECM enable accurate battery state estimation and performance prediction in these conditions. Examples of the enhanced ECM is derived using data-driven modeling techniques. Specifically, examples of the enhanced ECM focus on improving conventional ECM prediction under high C-rate discharge, where diffusion limitations can create a Li⁺ depleted region in the positive electrode, leading to rapid decrease in cell discharge capacity. Utilizing a discrepancy modeling framework, a single dynamic resistance (e.g., dependent on RC component overpotential) added to a conventional 2RC ECM is sufficient to capture the rapid voltage drop behavior. The dynamics of this model can be represented in a compact state-space form, with only one additional state compared to a 2 RC ECM.

To harness the full capability of the model architecture, in some examples the parameters are allowed to vary with the operating conditions. Moreover, the enhanced ECM model includes methods for improved parameter identification using an extensive characterization data set. The identification problem formulation focuses on ensuring smooth parameter tables and avoiding over-fitting with several regularization terms. Results indicate that the constant current pulses commonly used in ECM parameter identification may not be sufficient to match cell voltages under eVTOL-like power profiles. Thus, some examples of the enhanced ECM include an additional data set in the fitting process to improve the model fits.

In addition, the enhanced ECM model was validated against a flight data set, measured on large format commercial pouch cells. The flights are designed to cover a wide array of conditions expected for nominal and faulted eVTOL operations. A reserve time prediction accuracy was used as the most relevant metric for assessing model quality. This showed that the LD-ECM presented here can achieve an end-of-mission hover reserve duration prediction error distribution with a standard deviation of 6.2 seconds over all tested validation duty cycles. However, maximum reserve duration prediction errors as large as 20 seconds are observed. This is not unexpected given that the unstable voltage decay behavior is inherently highly sensitive to small parameter perturbations. These validation results are promising for predicting the voltage drop behavior under diffusion-limited cases sufficiently for eVTOL applications.

### Computer System

FIG. 19 shows a diagrammatic representation of the machine 1900 in the example form of a computer system (e.g., the EMS computer 110 or a ground support equipment control system) within which instructions 1904 (e.g., software, a program, an application, an applet, an app, or other executable code) for causing the machine 1900 to perform any one or more of the methodologies discussed herein may be executed. The instructions 1904 may transform the general, non-programmed machine 1900 into a particular machine 1900 programmed to carry out the described and illustrated functions in the manner described. In alternative examples, the machine 1900 operates as a standalone device or may be coupled (e.g., networked) to other machines. In a networked deployment, the machine 1900 may operate in the capacity of a server machine or a client machine in a server-client network environment, or as a peer machine in a peer-to-peer (or distributed) network environment. The machine 1900 may comprise, but not be limited to, a server computer, a client computer, a personal computer (PC), a tablet computer, a laptop computer, a netbook, a set-top box (STB), a PDA, an entertainment media system, a cellular telephone, a smart phone, a mobile device, a wearable device (e.g., a smart watch), a smart home device (e.g., a smart appliance), other smart devices, a web appliance, a network router, a network switch, a network bridge, or any machine capable of executing the instructions 1904, sequentially or otherwise, that specify actions to be taken by the machine 1900. Further, while only a single machine 1900 is illustrated, the term “machine” shall also be taken to include a collection of machines 1900 that individually or jointly execute the instructions 1904 to perform any one or more of the methodologies discussed herein.

The machine 1900 may include processors 1906, memory 1908, and I/O components 1902, which may be configured to communicate with each other such as via a bus 1910. In an example, the processors 1906 (e.g., a Central Processing Unit (CPU), a Reduced Instruction Set Computing (RISC) processor, a Complex Instruction Set Computing (CISC) processor, a Graphics Processing Unit (GPU), a Digital Signal Processor (DSP), an ASIC, a Radio-Frequency Integrated Circuit (RFIC), another processor, or any suitable combination thereof) may include, for example, a processor 1912 and a processor 1914 that may execute the instructions 1904. The term “processor” is intended to include multi-core processors that may comprise two or more independent processors (sometimes referred to as “cores”) that may execute instructions contemporaneously. Although FIG. 19 shows multiple processors 1906, the machine 1900 may include a single processor with a single core, a single processor with multiple cores (e.g., a multi-core processor), multiple processors with a single core, multiple processors with multiples cores, or any combination thereof.

The memory 1908 may include a main memory 1916, a static memory 1918, and a storage unit 1920, both accessible to the processors 1906 such as via the bus 1910. The main memory 1908, the static memory 1918, and storage unit 1920 store the instructions 1904 embodying any one or more of the methodologies or functions described herein. The instructions 1904 may also reside, completely or partially, within the main memory 1916, within the static memory 1918, within machine-readable medium 1922 within the storage unit 1920, within at least one of the processors 1906 (e.g., within the processor's cache memory), or any suitable combination thereof, during execution thereof by the machine 1900.

The I/O components 1902 may include a wide variety of components to receive input, provide output, produce output, transmit information, exchange information, capture measurements, and so on. The specific I/O components 1902 that are included in a particular machine will depend on the type of machine. For example, portable machines such as mobile phones will likely include a touch input device or other such input mechanisms, while a headless server machine will likely not include such a touch input device. It will be appreciated that the I/O components 1902 may include many other components that are not shown in FIG. 19. The I/O components 1902 are grouped according to functionality merely for simplifying the following discussion and the grouping is in no way limiting. In various examples, the I/O components 1902 may include output components 1924 and input components 1926. The output components 1924 may include visual components (e.g., a display such as a plasma display panel (PDP), a light emitting diode (LED) display, a liquid crystal display (LCD), a projector, or a cathode ray tube (CRT)), acoustic components (e.g., speakers), haptic components (e.g., a vibratory motor, resistance mechanisms), other signal generators, and so forth. The input components 1926 may include alphanumeric input components (e.g., a keyboard, a touch screen configured to receive alphanumeric input, a photo-optical keyboard, or other alphanumeric input components), point-based input components (e.g., a mouse, a touchpad, a trackball, a joystick, a motion sensor, or another pointing instrument), tactile input components (e.g., a physical button, a touch screen that provides location and/or force of touches or touch gestures, or other tactile input components), audio input components (e.g., a microphone), and the like.

In further examples, the I/O components 1902 may include biometric components 1928, motion components 1930, environmental components 1932, or position components 1934, among a wide array of other components. For example, the biometric components 1928 may include components to detect expressions (e.g., hand expressions, facial expressions, vocal expressions, body gestures, or eye tracking), measure biosignals (e.g., blood pressure, heart rate, body temperature, perspiration, or brain waves), identify a person (e.g., voice identification, retinal identification, facial identification, fingerprint identification, or electroencephalogram-based identification), and the like. The motion components 1930 may include acceleration sensor components (e.g., accelerometer), gravitation sensor components, rotation sensor components (e.g., gyroscope), and so forth. The environmental components 1732 may include, for example, illumination sensor components (e.g., photometer), temperature sensor components (e.g., one or more thermometers that detect ambient temperature), humidity sensor components, pressure sensor components (e.g., barometer), acoustic sensor components (e.g., one or more microphones that detect background noise), proximity sensor components (e.g., infrared sensors that detect nearby objects), gas sensors (e.g., gas detection sensors to detection concentrations of hazardous gases for safety or to measure pollutants in the atmosphere), or other components that may provide indications, measurements, or signals corresponding to a surrounding physical environment. The position components 1934 may include location sensor components (e.g., a GPS receiver component), altitude sensor components (e.g., altimeters or barometers that detect air pressure from which altitude may be derived), orientation sensor components (e.g., magnetometers), and the like.

Communication may be implemented using a wide variety of technologies. The I/O components 1902 may include communication components 1936 operable to couple the machine 1900 to a network 1938 or devices 1940 via a coupling 1942 and a coupling 1944, respectively. For example, the communication components 1936 may include a network interface component or another suitable device to interface with the network 1938. In further examples, the communication components 1936 may include wired communication components, wireless communication components, cellular communication components, Near Field Communication (NFC) components, Bluetooth® components (e.g., Bluetooth® Low Energy), Wi-Fi components, and other communication components to provide communication via other modalities. The devices 1940 may be another machine or any of a wide variety of peripheral devices (e.g., a peripheral device coupled via a USB).

Moreover, the communication components 1936 may detect identifiers or include components operable to detect identifiers. For example, the communication components 1936 may include Radio Frequency Identification (RFID) tag reader components, NFC smart tag detection components, optical reader components (e.g., an optical sensor to detect one-dimensional bar codes such as Universal Product Code (UPC) bar code, multi-dimensional bar codes such as Quick Response (QR) code, Aztec code, Data Matrix, Dataglyph, MaxiCode, PDF417, Ultra Code, UCC RSS-2D bar code, and other optical codes), or acoustic detection components (e.g., microphones to identify tagged audio signals). In addition, a variety of information may be derived via the communication components 1936, such as location via Internet Protocol (IP) geolocation, location via Wi-Fi® signal triangulation, location via detecting an NFC beacon signal that may indicate a particular location, and so forth.

### Executable Instructions and Machine Storage Medium

The various memories (i.e., memory 1908, main memory 1916, static memory 1918, and/or memory of the processors 1906) and/or storage unit 1920 may store data, such as a battery model, one or more sets of instructions and data structures (e.g., the look-up table 118) embodying or utilized by any one or more of the methodologies or functions described herein. These instructions and models (e.g., the instructions 1904), when executed by processors 1906, cause various operations to implement the disclosed examples.

As used herein, the terms “machine-storage medium,” “device-storage medium,” “computer-storage medium” mean the same thing and may be used interchangeably in this disclosure. The terms refer to a single or multiple storage devices and/or media (e.g., a centralized or distributed database, and/or associated caches and servers) that store executable instructions and/or data. The terms shall accordingly be taken to include, but not be limited to, solid-state memories, and optical and magnetic media, including memory internal or external to processors. Specific examples of machine-storage media, computer-storage media and/or device-storage media include non-volatile memory, including by way of example semiconductor memory devices, e.g., erasable programmable read-only memory (EPROM), electrically erasable programmable read-only memory (EEPROM), FPGA, and flash memory devices; magnetic disks such as internal hard disks and removable disks; magneto-optical disks; and CD-ROM and DVD-ROM disks. The terms “machine-storage media,” “computer-storage media,” and “device-storage media” specifically exclude carrier waves, modulated data signals, and other such media, at least some of which are covered under the term “signal medium” discussed below.

### Transmission Medium

In various examples, one or more portions of the network 1938 may be an ad hoc network, an intranet, an extranet, a VPN, a LAN, a WLAN, a WAN, a WWAN, a MAN, the Internet, a portion of the Internet, a portion of the PSTN, a plain old telephone service (POTS) network, a cellular telephone network, a wireless network, a Wi-Fi® network, another type of network, or a combination of two or more such networks. For example, the network 1938 or a portion of the network 1938 may include a wireless or cellular network, and the coupling 1942 may be a Code Division Multiple Access (CDMA) connection, a Global System for Mobile communications (GSM) connection, or another type of cellular or wireless coupling. In this example, the coupling 1942 may implement any of a variety of types of data transfer technology, such as Single Carrier Radio Transmission Technology (1×RTT), Evolution-Data Optimized (EVDO) technology, General Packet Radio Service (GPRS) technology, Enhanced Data rates for GSM Evolution (EDGE) technology, third Generation Partnership Project (3GPP) including 3G, fourth generation wireless (4G) networks, Universal Mobile Telecommunications System (UMTS), High Speed Packet Access (HSPA), Worldwide Interoperability for Microwave Access (WiMAX), Long Term Evolution (LTE) standard, others defined by various standard-setting organizations, other long range protocols, or other data transfer technology.

The instructions 1904 may be transmitted or received over the network 1938 using a transmission medium via a network interface device (e.g., a network interface component included in the communication components 1936) and utilizing any one of a number of well-known transfer protocols (e.g., hypertext transfer protocol (HTTP)). Similarly, the instructions 1904 may be transmitted or received using a transmission medium via the coupling 1944 (e.g., a peer-to-peer coupling) to the devices 1940. The terms “transmission medium” and “signal medium” mean the same thing and may be used interchangeably in this disclosure. The terms “transmission medium” and “signal medium” shall be taken to include any intangible medium that is capable of storing, encoding, or carrying the instructions 1904 for execution by the machine 1900, and includes digital or analog communications signals or other intangible media to facilitate communication of such software. Hence, the terms “transmission medium” and “signal medium” shall be taken to include any form of modulated data signal, carrier wave, and so forth. The term “modulated data signal” means a signal that has one or more of its characteristics set or changed in such a matter as to encode information in the signal.

### Computer-Readable Medium

The terms “machine-readable medium,” “computer-readable medium” and “device-readable medium” mean the same thing and may be used interchangeably in this disclosure. The terms are defined to include both machine-storage media and transmission media. Thus, the terms include both storage devices/media and carrier waves/modulated data signals.

### Example Technical Problems

The described examples of a battery management system (BMS) with an enhanced equivalent circuit model (ECM) seeks to address some example technical problems associated with managing battery performance. Following are some examples of these problems, along with descriptions of how examples of the battery management system (BMS) with an enhanced equivalent circuit model (ECM) may provide solutions.

### Rapid Voltage Drop Under High Discharge Rates

Lithium-ion batteries can experience rapid voltage drops when subjected to high discharge rates, which can occur during intense operational demands or fault conditions in eVTOL aircraft. The described examples incorporates an enhanced ECM that dynamically adjusts a series resistance component based on real-time operational data from the battery. This adjustment models lithium depletion effects under high discharge conditions. The enhanced ECM includes multiple resistor-capacitor (RC) pairs, and the series resistance component is integrated in series with these RC pairs, allowing for precise modeling of the battery's internal resistance changes that lead to voltage drops. This dynamic adjustment helps prevent sudden power loss and maintains stable aircraft operation.

### Inaccurate Battery State Estimation

Traditional battery management systems may struggle with accurately estimating the state of charge and health of batteries under varying operational conditions, leading to inefficiencies and potential safety risks. Examples of the BMS uses the enhanced ECM to continuously refine parameters by analyzing discrepancies between predicted and actual battery performance. This refinement is based on real-time changes in state of charge, temperature, and current, ensuring that the battery's estimated state reflects its actual condition. For instance, the BMS processes sensor data to recalibrate resistance values or update state of charge estimation, enhancing the accuracy of the battery state estimation and thereby optimizing the operational readiness and safety of the eVTOL aircraft.

### Degradation of Battery Performance Over Time

Batteries degrade over time due to various factors such as temperature fluctuations, high discharge rates, and aging, which can compromise the performance and longevity of the battery. Examples of the enhanced ECM within the BMS includes an environmental adaptation module that dynamically adjusts model parameters in response to detected environmental conditions such as temperature, humidity, and atmospheric pressure. This feature helps in modeling the effects of environmental factors on battery degradation accurately. By adjusting the ECM parameters to compensate for these factors, the BMS can extend the battery's operational life and maintain its performance within safe limits, even under challenging conditions.

### Need for Customization Across Different Vehicle Types

Different types of electric vehicles, including eVTOLs, may require specific battery management strategies to accommodate their unique operational profiles and power requirements. Exampled of the enhanced ECM is adaptable for use in various types of electric vehicles by customizing the model parameters to reflect typical operating conditions and discharge rates specific to each vehicle type. This customization allows the BMS to be effectively implemented across different platforms, ensuring optimal battery management tailored to the specific needs of each vehicle type, thereby enhancing overall efficiency and performance.

### Example Statements

Example 1 is a battery management system for an electric vertical takeoff and landing (eVTOL) aircraft, comprising: a memory to store: an equivalent circuit model (ECM) configured to dynamically adjust a series resistance component in real-time based on operational data from a lithium-ion battery, wherein the series resistance component models lithium depletion effects under high discharge; and at least one processor configured to: continuously refine parameters of the ECM by analyzing discrepancies between predicted and actual battery performance, wherein the adjustments to the series resistance component are based on real-time changes in state of charge, temperature, and current.

In Example 2, the subject matter of Example 1 includes, wherein the series resistance component is adjustable using a data-driven discrepancy model that identifies modifications to align ECM predictions with observed battery performance.

In Example 3, the subject matter of Example 2 includes, wherein the data-driven discrepancy model uses sparse regression to determine dynamical system corrections based on prediction errors.

In Example 4, the subject matter of Examples 1-3 includes, wherein the ECM includes multiple resistor-capacitor (RC) pairs, and the series resistance component is integrated in series with these RC pairs.

In Example 5, the subject matter of Example 4 includes, wherein the parameters of the RC pairs and the series resistance component are adaptively modified based on a combination of inputs including state of charge, temperature, and current.

In Example 6, the subject matter of Examples 1-5 includes, wherein the operational data is derived from sensors configured to measure temperature, state of charge, and current directly from the battery during the operation of the eVTOL aircraft.

In Example 7, the subject matter of Examples 1-6 includes, a display interface configured to provide real-time and predictive battery performance metrics based on the refined parameters of the ECM.

In Example 8, the subject matter of Examples 1-7 includes, wherein the ECM is configured to predict battery terminal voltage under extreme discharge conditions, including fault scenarios in the eVTOL aircraft.

In Example 9, the subject matter of Examples 1-8 includes, wherein the ECM is adaptable for use in various types of electric vehicles by customizing the model parameters to reflect operating conditions and discharge rates specific to each vehicle type.

In Example 10, the subject matter of Examples 1-9 includes, wherein the ECM further includes an environmental adaptation module that dynamically adjusts model parameters in response to detected environmental conditions such as temperature, humidity, and atmospheric pressure during flight.

Example 11 is a method for managing battery performance in an electric vertical takeoff and landing (eVTOL) aircraft, the method comprising: dynamically adjusting a series resistance component of an equivalent circuit model (ECM) in real-time based on operational data from a lithium-ion battery to model lithium depletion effects under high discharge rates; and continuously refining parameters of the ECM by analyzing discrepancies between predicted battery performance and actual battery performance using a processor, wherein the adjustments are based on real-time changes in state of charge, temperature, and current.

In Example 12, the subject matter of Example 11 includes, wherein dynamically adjusting the series resistance component comprises employing a data-driven discrepancy model that identifies minimal modifications required to align ECM predictions with observed battery performance.

In Example 13, the subject matter of Examples 11-12 includes, wherein analyzing discrepancies comprises using a data-driven discrepancy model that involves using sparse regression to determine dynamical system corrections based on prediction errors.

In Example 14, the subject matter of Examples 11-13 includes, integrating the series resistance component in series with multiple resistor-capacitor (RC) pairs within the ECM.

In Example 15, the subject matter of Example 14 includes, wherein refining parameters includes adaptively modifying the parameters of the RC pairs and the series resistance component based on a combination of inputs including state of charge, temperature, and current.

In Example 16, the subject matter of Examples 11-15 includes, wherein operational data is obtained from sensors configured to measure temperature, state of charge, and current directly from the battery during operation of the eVTOL aircraft.

In Example 17, the subject matter of Examples 11-16 includes, displaying real-time and predictive battery performance metrics based on the refined parameters of the ECM on a display interface.

In Example 18, the subject matter of Examples 11-17 includes, wherein the ECM is configured to predict battery terminal voltage under extreme discharge conditions, including fault scenarios in the eVTOL aircraft.

In Example 19, the subject matter of Examples 11-18 includes, wherein adapting the ECM for use in various types of electric vehicles comprises customizing the model parameters to reflect operating conditions and discharge rates specific to each vehicle type.

In Example 20, the subject matter of Examples 11-19 includes, dynamically adjusting model parameters in response to detected environmental conditions such as temperature, humidity, and atmospheric pressure during flight using an environmental adaptation module within the ECM.

Example 21 is a battery management system to predict performance of a lithium-ion battery in an electric vertical takeoff and landing (eVTOL) aircraft, the battery management system comprising: at least one memory storing n enhanced equivalent circuit model (ECM) configured to dynamically adjust a series resistance component in real-time based on operational data of the battery, wherein the series resistance component models lithium depletion effects under high discharge rates; and at least one data processing unit configured to analyze discrepancies between predicted battery performance and actual battery performance to refine parameters of the enhanced ECM continuously, wherein the enhanced ECM integrates real-time updates of the series resistance component based on at least one of state of charge, temperature, and current of the battery.

In Example 22, the subject matter of Example 21 includes, wherein the series resistance component is adjusted continuously based on a data-driven discrepancy model that identifies modifications required to align the enhanced ECM predictions with actual battery performance data.

In Example 23, the subject matter of Example 22 includes, wherein the data-driven discrepancy model employs sparse regression techniques.

In Example 24, the subject matter of Examples 21-23 includes, wherein the enhanced ECM further comprises at least one resistor-capacitor (RC) pair, and the series resistance component in series with the at least one RC pair.

In Example 25, the subject matter of Example 24 includes, wherein the parameters of the RC pair and the series resistance component vary adaptively based on a multi-dimensional input comprising state of charge, temperature, and current.

In Example 26, the subject matter of Examples 21-25 includes, wherein the operational data includes data collected from sensors measuring real-time temperature, state of charge, and current of the battery during operation of the eVTOL aircraft.

In Example 27, the subject matter of Examples 21-26 includes, a user interface configured to display predicted battery performance metrics and updates based on the refined parameters of the enhanced ECM.

In Example 28, the subject matter of Examples 21-27 includes, wherein the enhanced ECM is configured to predict terminal voltage of the battery under conditions exceeding normal operational discharge rates.

In Example 29, the subject matter of Examples 21-28 includes, wherein the enhanced ECM is applicable to a range of electric vehicles including drones, electric cars, and marine vehicles by adjusting the model parameters specific to operating conditions and discharge rates of each vehicle type.

In Example 30, the subject matter of Examples 21-29 includes, wherein the enhanced ECM includes an environmental adaptation module that adjusts the model parameters based on external environmental conditions detected during flight, including but not limited to temperature, humidity, and atmospheric pressure.

Example 31 is a method to simulate a battery cell, the method comprising: providing an equivalent circuit model (ECM) of the battery cell comprising a plurality of resistor-capacitor (RC) pairs and a variable resistor configured to model knee-drop dynamics; determining a set of operating conditions comprising a temperature, a state of charge (SOC), and a discharge current profile; identifying a set of model parameters by referring to multidimensional lookup tables indexed by SOC, temperature, and discharge current; configuring the ECM using the identified set of model parameters; numerically integrating the ECM over time using the set of operating conditions to generate simulated voltage response data; and outputting the simulated voltage response data.

In Example 32, the subject matter of Example 31 includes, wherein the variable resistor has a resistance value that varies according to a differential equation dependent on total overpotential of the RC pairs.

In Example 33, the subject matter of Examples 31-32 includes, wherein the set of model parameters comprises resistances and capacitances associated with the plurality of RC pairs.

In Example 34, the subject matter of Examples 31-33 includes, wherein the set of model parameters further comprises a self-growth rate coefficient, an activation function coefficient, and an overpotential threshold associated with the variable resistor.

In Example 35, the subject matter of Examples 31-34 includes, wherein numerically integrating the ECM comprises utilizing an ordinary differential equation (ODE) solver.

In Example 36, the subject matter of Example 35 includes, wherein the ODE solver adaptively controls a timestep size based on a rate of change of the simulated voltage response.

In Example 37, the subject matter of Example undefined includes, providing the simulated voltage response data to a battery management system of a vehicle; and the battery management system performing one or more control actions based on the simulated voltage response data.

In Example 38, the subject matter of Example 37 includes, wherein the one or more control actions comprise one or more of: limiting a discharge rate of the battery cell; balancing a state of charge of the battery cell with other cells; and scheduling maintenance for the battery cell.

In Example 39, the subject matter of Examples 31-38 includes, providing the simulated voltage response data to a computing device, the computing device to determine at least one of a remaining flight time and a range of an electric aerial vehicle based on the simulated voltage response data.

In Example 40, the subject matter of Examples 31-39 includes, wherein numerically integrating the ECM comprises: simulating a fault condition comprising loss of battery power; and determining that the simulated voltage response violates a safety limit during the fault condition.

Example 41 is a system to simulate a battery cell, the system comprising: memory storing: an equivalent circuit model (ECM) of the battery cell comprising a plurality of resistor-capacitor (RC) pairs and a variable resistor configured to model knee-drop dynamics; and at least one lookup table indexed by state of charge (SOC), temperature, and discharge current; a processor configured to: access a set of operating conditions to simulate the ECM; identify a set of model parameters by referring to the at least one lookup table; numerically integrate the ECM over time using the set of operating conditions to generate simulated voltage response data; and output the simulated voltage response data.

In Example 42, the subject matter of Example 41 includes, wherein the processor is configured to adaptively control a timestep size during numerical integration based on a rate of change of the simulated voltage response.

In Example 43, the subject matter of Example 42 includes, wherein the at least one lookup tables is generated from laboratory cell characterization data.

Example 44 is a method for estimating flight range of an electric aircraft, the method comprising: receiving at a computer flight plan details for the electric aircraft; generating a load profile estimating power draw over a flight plan based on the flight plan details; simulating a battery model comprising a variable resistor configured to model a knee-drop phenomenon using the generated load profile and to determine a voltage response of the battery model over the flight plan; determining total usable energy of the battery model based on the simulated voltage response; and calculating an estimated achievable flight range based on the total usable energy.

In Example 45, the subject matter of Example 44 includes, wherein the flight plan details comprise one or more of total flight distance, aircraft weight, cruise speed, cruise altitude, and wind forecasts.

In Example 46, the subject matter of Examples 44-45 includes, wherein generating the load profile comprises estimating power draw for different phases of flight including takeoff, climb, cruise, descent, and reserves.

In Example 47, the subject matter of Examples 44-46 includes, wherein the battery model accounts for nonlinear dynamics in the voltage response.

In Example 48, the subject matter of Example 47 includes, wherein the nonlinear dynamics comprise the knee-drop phenomenon at high discharge rates.

In Example 49, the subject matter of Examples 44-48 includes, wherein simulating the battery model comprises numerically integrating electrical dynamics equations of an enhanced equivalent circuit model.

In Example 50, the subject matter of Example 49 includes, adapting parameters of the enhanced equivalent circuit model based on measured data for a battery.

In Example 51, the subject matter of Examples 44-50 includes, wherein determining total usable energy comprises integrating power over time based on current and simulated voltage at each time step.

In Example 52, the subject matter of Examples 44-51 includes, displaying the estimated achievable flight range for flight planning.

In Example 53, the subject matter of Examples 44-52 includes, updating parameters of the battery model to account for changes in battery state.

Example 54 is a method for integrating an enhanced equivalent circuit model (ECM) into a battery management system (BMS) of an electric vertical takeoff and landing (eVTOL) aircraft, the method comprising: ∘programming the BMS to utilize the ECM and associated lookup tables (LUTs) for real-time state estimation and performance prediction of lithium-ion batteries under varying operational conditions.

In Example 55, the subject matter of Example 54 includes, wherein the ECM includes a dynamic series resistance component to account for lithium depletion at high discharge rates.

In Example 56, the subject matter of Examples 54-55 includes, updating the LUTs based on data collected from operational flights of the eVTOL aircraft.

In Example 57, the subject matter of Examples 54-56 includes, wherein the LUTs store pre-computed values of model parameters that vary with at least one of state of charge, temperature, and discharge current.

In Example 58, the subject matter of Examples 54-57 includes, recalibrating the ECM based on feedback received from the BMS regarding battery performance and operational efficiency.

In Example 59, the subject matter of Example 58 includes, wherein the feedback includes data related to battery aging effects observed during eVTOL operations.

In Example 60, the subject matter of Examples 54-59 includes, wherein the real-time state estimation includes predicting the remaining useful life and available energy capacity of the battery.

In Example 61, the subject matter of Examples 54-60 includes, wherein the performance prediction includes calculating the expected battery behavior during emergency scenarios requiring high discharge rates.

In Example 62, the subject matter of Examples 54-61 includes, implementing safety checks within the BMS based on outputs from the ECM to ensure operational safety during flights.

In Example 63, the subject matter of Example 62 includes, wherein the safety checks predict the ability of the battery to meet power demands during critical flight phases.

Expanding on Example 63, the method involves detailed procedures for evaluating the battery's capacity to handle specific power requirements during phases such as takeoff, landing, and emergency maneuvers. The safety checks utilize predictive algorithms that analyze data from the ECM, such as voltage levels, current draw, and temperature, to assess whether the battery can sustain the required power output without exceeding safety thresholds.

For instance, during takeoff, the BMS might calculate the expected power draw and compare it with the battery's current state of charge and health as predicted by the ECM. If the power required exceeds what the battery can safely provide, the system could trigger preventive measures, such as reducing power usage in non-critical systems or alerting the pilot to modify the flight plan.

Furthermore, these safety checks can be dynamically adjusted based on real-time data. For example, if an unexpected drop in battery performance is detected during flight, the BMS can immediately recalculate the power availability and adjust the flight operations to maintain safety margins. This dynamic adjustment is supported by continuously updating the ECM's parameters and LUTs with the latest operational data, ensuring that the model reflects the most current state of the battery.

Additionally, the safety checks include simulations of various flight scenarios to predict battery behavior under different conditions. These simulations help in identifying potential issues before they occur, allowing for preemptive adjustments to flight operations or maintenance schedules. This proactive approach aids in maintaining high safety standards and operational reliability of the eVTOL aircraft under various conditions.

In Example 64, the subject matter of Examples 54-63 includes, wherein the ECM is updated periodically based on a comparison of predicted and actual battery performance data.

In Example 65, the subject matter of Examples 54-64 includes, utilizing a discrepancy modeling framework to enhance the ECM by identifying and incorporating dynamic resistances that explain observed prediction errors.

In Example 66, the subject matter of Examples 54-65 includes, wherein the BMS adjusts operational strategies for the eVTOL aircraft based on predictions made by the ECM.

In Example 67, the subject matter of Examples 54-66 includes, wherein the ECM and LUTs are integrated into a centralized control system of the eVTOL aircraft to provide unified management of multiple battery packs.

In Example 68, the subject matter of Examples 54-67 includes, employing a regularization technique during the ECM parameterization to ensure smooth transitions of model parameters across different operational conditions.

Example 69 is a method for operational deployment of an enhanced equivalent circuit model (ECM) within a battery management system (BMS) of an electric vertical takeoff and landing (eVTOL) aircraft, the method comprising: ∘continuously monitoring the battery's state and predicting future performance using the ECM, and ∘performing safety checks based on the model's output to ensure the battery can meet power demands during flight phases.

In Example 70, the subject matter of Example 69 includes, wherein the continuous monitoring includes real-time updates of battery state of charge (SOC), state of health (SOH), and temperature.

In Example 71, the subject matter of Examples 69-70 includes, wherein predicting future performance involves using lookup tables (LUTs) that contain pre-computed values of battery parameters under various conditions.

In Example 72, the subject matter of Examples 69-71 includes, wherein the safety checks include evaluating the battery's ability to handle emergency scenarios that require high discharge rates.

In Example 73, the subject matter of Examples 69-72 includes, adjusting flight control strategies based on the predictions of battery performance to enhance flight safety and efficiency.

In Example 74, the subject matter of Examples 69-73 includes, wherein the ECM incorporates dynamic series resistance components to account for lithium depletion effects during high discharge rates.

In Example 75, the subject matter of Examples 69-74 includes, providing alerts to pilots based on the ECM outputs, indicating potential battery-related issues before they affect flight operations.

At a high level, the method involves the battery management system (BMS) utilizing outputs from the enhanced equivalent circuit model (ECM) to generate alerts for pilots. These alerts are designed to inform about the battery's status or any deviations from normal operational parameters that might impact flight safety or performance.

In more specific examples, the alerts generated by the BMS may include visual or auditory signals on the aircraft's dashboard. These alerts are triggered based on predefined criteria evaluated by the ECM, such as voltage drops, high current draws, or abnormal temperature readings. The ECM continuously monitors these parameters against the battery's performance data and operational thresholds to ensure timely notification.

In even more specific examples, the ECM may utilize complex algorithms to predict potential battery failures based on historical data and real-time monitoring. For instance, if the ECM detects a consistent pattern of temperature increase that could lead to thermal runaway, it triggers an alert for preemptive maintenance checks. Similarly, if the discharge rate exceeds the safe operational limits during high-power maneuvers, the pilot would receive an immediate warning to adjust the power usage. These alerts are for maintaining operational safety and can be customized based on different flight profiles and battery conditions.

In Example 76, the subject matter of Examples 69-75 includes, wherein the ECM is recalibrated based on accumulated flight data to improve prediction accuracy over time.

In Example 77, the subject matter of Examples 69-76 includes, integrating the ECM outputs into the eVTOL aircraft's central flight control system for automated decision-making.

In Example 78, the subject matter of Examples 69-77 includes, wherein the safety checks are performed before each takeoff and landing to ensure battery reliability during these flight phases.

In Example 79, the subject matter of Examples 69-78 includes, wherein the ECM utilizes data-driven modeling techniques to enhance the accuracy of battery behavior predictions under variable operational conditions.

In Example 80, the subject matter of Examples 69-79 includes, employing a feedback loop within the BMS to adjust the ECM based on discrepancies between predicted and actual battery performance.

In Example 81, the subject matter of Examples 69-80 includes, wherein the BMS uses the ECM to optimize power distribution among multiple battery packs in the eVTOL aircraft.

At a high level, the method involves the battery management system (BMS) leveraging the enhanced equivalent circuit model (ECM) to manage and distribute power efficiently across multiple battery packs within the eVTOL aircraft. This process helps in maintaining balanced energy usage and prolonging the battery life during flights.

In more specific examples, the BMS dynamically adjusts the load shared between battery packs based on real-time data provided by the ECM. This includes assessing each battery pack's current state of charge, health, and capacity to contribute to the overall power needs. For instance, if one battery pack shows signs of lower performance, the BMS can reduce its load and redistribute it among other packs to prevent overstrain and potential failure.

In even more specific examples, the ECM may employ sophisticated algorithms to predict future states of each battery pack based on usage patterns and operational conditions. For example, during a flight, the ECM may calculate the expected depletion rates of each pack and adjust the power distribution to ensure that multiple packs reach their lower charge limits simultaneously. This strategy avoids scenarios where one pack becomes significantly more depleted than others, which can reduce overall system efficiency and increase wear on individual batteries. The ECM might also consider environmental factors such as temperature, which can affect battery performance, to optimize power distribution dynamically throughout the flight.

In Example 82, the subject matter of Examples 69-81 includes, wherein the ECM predictions are used to plan and adjust flight routes and durations based on the current battery capacity and expected energy usage.

In Example 83, the subject matter of Examples 69-82 includes, using the ECM to simulate potential future battery states under hypothetical emergency scenarios to prepare and plan appropriate responses.

Example 84 is a method for continuous improvement of an enhanced equivalent circuit model (ECM) within a battery management system (BMS) of an electric vertical takeoff and landing (eVTOL) aircraft, the method comprising: ∘continuously collecting operational data from the eVTOL aircraft during flights, and ∘periodically updating the ECM parameters and lookup tables (LUTs) based on the collected data to refine and enhance the model's accuracy and reliability.

In Example 85, the subject matter of Example 84 includes, wherein the operational data includes battery performance metrics such as voltage, current, temperature, and state of charge (SOC).

In Example 86, the subject matter of Examples 84-85 includes, wherein updating the ECM parameters involves recalibrating a dynamic series resistance component to better represent lithium depletion effects under high discharge rates.

In Example 87, the subject matter of Examples 84-86 includes, using machine learning algorithms to analyze the collected data and identify patterns or anomalies that indicate changes in battery behavior.

At a high level, the method involves the application of machine learning algorithms to process and analyze data collected from the battery management system (BMS). These algorithms are designed to detect patterns or deviations in battery performance, which can help in predicting potential issues or optimizing battery usage.

In more specific examples, various machine learning models, such as regression analysis, clustering, or neural networks, are employed to interpret data generated by the batteries during operation. These models may identify subtle changes in battery voltage, current, temperature, and other critical parameters that might not be immediately apparent. For instance, a sudden change in the battery's temperature gradient could be flagged as an anomaly, prompting further investigation.

In even more specific examples, advanced machine learning techniques like deep learning could be used to predict battery degradation over time based on historical and real-time operational data. For example, a recurrent neural network (RNN) may be trained to forecast future battery capacities and health states by learning from sequences of past performance data under various load conditions and environmental factors. This predictive capability allows for proactive maintenance scheduling and operational adjustments to extend the battery's useful life and ensure safety. Additionally, anomaly detection algorithms could continuously monitor for out-of-pattern behaviors, automatically adjusting operational parameters or alerting maintenance teams to prevent failures before they occur.

In Example 88, the subject matter of Examples 84-87 includes, wherein the LUTs are updated to reflect changes in battery characteristics due to aging or environmental factors.

In Example 89, the subject matter of Examples 84-88 includes, implementing a feedback loop within the BMS to automatically suggest updates to the ECM based on deviations between predicted and actual battery performance.

In Example 90, the subject matter of Examples 84-89 includes, wherein the collected data is used to perform a validation of the ECM under various flight conditions and operational scenarios.

In Example 91, the subject matter of Examples 84-90 includes, integrating the updated ECM into the eVTOL aircraft's flight control systems to enhance real-time decision-making capabilities.

In Example 92, the subject matter of Examples 84-91 includes, wherein the periodic updates are scheduled based on the frequency of identified discrepancies in battery performance predictions.

In Example 93, the subject matter of Examples 84-92 includes documenting changes in battery performance over time to create a historical database that supports long-term improvements in battery management strategies.

In Example 94, the subject matter of Examples 84-93 includes, wherein updates to the ECM are tested in a simulation environment before being deployed to operational BMS.

In Example 95, the subject matter of Examples 84-94 includes, adjusting operational thresholds within the BMS based on updated ECM parameters to optimize battery usage and prolong battery life.

In Example 96, the subject matter of Examples 84-95 includes, wherein the updates to the LUTs include adjustments for temperature and SOC dependencies based on newly collected data.

In Example 97, the subject matter of Examples 84-96 includes, using the updated ECM to provide predictions of battery end-of-life and replacement schedules.

Example 98 is at least one machine-readable medium including instructions that, when executed by processing circuitry, cause the processing circuitry to perform operations to implement of any of Examples 1-97.

Example 99 is an apparatus comprising means to implement of any of Examples 1-97.

Example 100 is a system to implement any of Examples 1-97.

Example 101 is a method to implement any of Examples 1-97.

What is claimed is:

1. A battery management system for an electric vertical takeoff and landing (eVTOL) aircraft, comprising:
a memory to store:
an equivalent circuit model (ECM) configured to dynamically adjust a series resistance component in real-time based on operational data from a lithium-ion battery, wherein the series resistance component models lithium depletion effects under high discharge; and
at least one processor configured to:
continuously refine parameters of the ECM by analyzing discrepancies between predicted and actual battery performance, wherein the adjustments to the series resistance component are based on real-time changes in state of charge, temperature, and current.

2. The battery management system of claim 1, wherein the series resistance component is adjustable using a data-driven discrepancy model that identifies modifications to align ECM predictions with observed battery performance.

3. The battery management system of claim 2, wherein the data-driven discrepancy model uses sparse regression to determine dynamical system corrections based on prediction errors.

4. The battery management system of claim 1, wherein the ECM includes multiple resistor-capacitor (RC) pairs, and the series resistance component is integrated in series with these RC pairs.

5. The battery management system of claim 4, wherein the parameters of the RC pairs and the series resistance component are adaptively modified based on a combination of inputs including state of charge, temperature, and current.

6. The battery management system of claim 1, wherein the operational data is derived from sensors configured to measure temperature, state of charge, and current directly from the battery during the operation of the eVTOL aircraft.

7. The battery management system of claim 1, further comprising a display interface configured to provide real-time and predictive battery performance metrics based on the refined parameters of the ECM.

8. The battery management system of claim 1, wherein the ECM is configured to predict battery terminal voltage under extreme discharge conditions, including fault scenarios in the eVTOL aircraft.

9. The battery management system of claim 1, wherein the ECM is adaptable for use in various types of electric vehicles by customizing the model parameters to reflect operating conditions and discharge rates specific to each vehicle type.

10. The battery management system of claim 1, wherein the ECM further includes an environmental adaptation module that dynamically adjusts model parameters in response to detected environmental conditions such as temperature, humidity, and atmospheric pressure during flight.

11. A method for managing battery performance in an electric vertical takeoff and landing (eVTOL) aircraft, the method comprising:
dynamically adjusting a series resistance component of an equivalent circuit model (ECM) in real-time based on operational data from a lithium-ion battery to model lithium depletion effects under high discharge rates; and
continuously refining parameters of the ECM by analyzing discrepancies between predicted battery performance and actual battery performance using a processor, wherein the adjustments are based on real-time changes in state of charge, temperature, and current.

12. The method of claim 11, wherein dynamically adjusting the series resistance component comprises employing a data-driven discrepancy model that identifies minimal modifications required to align ECM predictions with observed battery performance.

13. The method of claim 11, wherein analyzing discrepancies comprises using a data-driven discrepancy model that involves using sparse regression to determine dynamical system corrections based on prediction errors.

14. The method of claim 11, further comprising integrating the series resistance component in series with multiple resistor-capacitor (RC) pairs within the ECM.

15. The method of claim 14, wherein refining parameters includes adaptively modifying the parameters of the RC pairs and the series resistance component based on a combination of inputs including state of charge, temperature, and current.

16. The method of claim 11, wherein operational data is obtained from sensors configured to measure temperature, state of charge, and current directly from the battery during operation of the eVTOL aircraft.

17. The method of claim 11, further comprising displaying real-time and predictive battery performance metrics based on the refined parameters of the ECM on a display interface.

18. The method of claim 11, wherein the ECM is configured to predict battery terminal voltage under extreme discharge conditions, including fault scenarios in the eVTOL aircraft.

19. The method of claim 11, wherein adapting the ECM for use in various types of electric vehicles comprises customizing the model parameters to reflect operating conditions and discharge rates specific to each vehicle type.

20. The method of claim 11, further comprising dynamically adjusting model parameters in response to detected environmental conditions such as temperature, humidity, and atmospheric pressure during flight using an environmental adaptation module within the ECM.
